(19) United States
(12) Patent Application Publication
(10) Pub. No.: US 2023/0023327 A1
(43) Pub. Date: Jan. 26, 2023

(54) SEMICONDUCTOR STORAGE DEVICE

(71) Applicant: Kioxia Corporation, Tokyo (JP)

(72) Inventors: Satoshi NAGASHIMA, Yokkaichi (JP); Yefei HAN, Yokkaichi (JP)

(73) Assignee: Kioxia Corporation, Tokyo (JP)

(21) Appl. No.: 17/807,050

(22) Filed: Jun. 15, 2022

(30) Foreign Application Priority Data
Jul. 21, 2021 (JP) 2021-121032

(51) Int. Cl. H01L 27/11597; H01L 27/11587; H01L 29/78

(52) U.S. Cl. CPC H01L 27/11597; H01L 27/11587; H01L 29/78391

(57) ABSTRACT

A semiconductor storage device according to an embodiment includes a substrate, a first word line, a second word line, a first channel, a first memory film, a second channel, a second memory film, a first insulating layer, a first source line, and a first drain line. The second word line is separated from the first word line in a second direction. The first channel is aligned with the first word line in a third direction. The second channel is aligned with the second word line in the third direction. The first insulating layer is positioned between the first word line and the second word line in the second direction and between the first channel and the second channel in the second direction. The first source line and first drain line extend in the second direction.

### CROSS-REFERENCE TO RELATED APPLICATION

This application is based upon and claims the benefit of priority from Japanese Patent Application No. 2021-121032, filed Jul. 21, 2021; the entire contents of which are incorporated herein by reference.

### FIELD

Embodiments described herein relate generally to a semiconductor storage device.

### BACKGROUND ART

A semiconductor storage device including a multi-layered body in which an insulating layer and a word line are alternately stacked in a thickness direction of a substrate and a channel penetrating the multi-layered body in the thickness direction of the substrate is known.

### BRIEF DESCRIPTION OF THE DRAWINGS

FIG. 1 is a perspective cross-sectional view showing a semiconductor storage device according to a first embodiment.

FIG. 2 is a cross-sectional view taken along line F2-F2 of the semiconductor storage device shown in FIG. 1.

FIG. 3 is a cross-sectional view taken along line F3-F3 of the semiconductor storage device shown in FIG. 1.

FIG. 4A is a diagram showing an equivalent circuit of the semiconductor storage device according to the first embodiment.

FIG. 4B is a diagram showing an equivalent circuit of a modified example of the semiconductor storage device according to the first embodiment.

FIG. 5A is a perspective cross-sectional view for explaining a method of manufacturing the semiconductor storage device according to the first embodiment.

FIG. 5B is a perspective cross-sectional view for explaining the method of manufacturing the semiconductor storage device according to the first embodiment.

FIG. 5C is a perspective cross-sectional view for explaining the method of manufacturing the semiconductor storage device according to the first embodiment.

FIG. 5D is a perspective cross-sectional view for explaining the method of manufacturing the semiconductor storage device according to the first embodiment.

FIG. 5E is a perspective cross-sectional view for explaining the method of manufacturing the semiconductor storage device according to the first embodiment.

FIG. 5F is a perspective cross-sectional view for explaining the method of manufacturing the semiconductor storage device according to the first embodiment.

FIG. 5G is a perspective cross-sectional view for explaining the method of manufacturing the semiconductor storage device according to the first embodiment.

FIG. 5H is a perspective cross-sectional view for explaining the method of manufacturing the semiconductor storage device according to the first embodiment.

FIG. 5I is a perspective cross-sectional view for explaining the method of manufacturing the semiconductor storage device according to the first embodiment.

FIG. 5J is a perspective cross-sectional view for explaining the method of manufacturing the semiconductor storage device according to the first embodiment.

FIG. 6A is a cross-sectional view for explaining a method of manufacturing the semiconductor storage device according to the first embodiment.

FIG. 6B is a cross-sectional view for explaining the method of manufacturing the semiconductor storage device according to the first embodiment.

FIG. 6C is a cross-sectional view for explaining the method of manufacturing the semiconductor storage device according to the first embodiment.

FIG. 6D is a cross-sectional view for explaining the method of manufacturing the semiconductor storage device according to the first embodiment.

FIG. 7 is a diagram showing one application example of a structure according to the first embodiment.

FIG. 8 is a view for explaining one application example of the structure according to the first embodiment.

FIG. 9 is a view for explaining one application example of the structure according to the first embodiment.

FIG. 10 is a view for explaining one application example of the structure according to the first embodiment.

FIG. 11 is a perspective cross-sectional view showing a semiconductor storage device according to a second embodiment.

FIG. 12 is a cross-sectional view showing a semiconductor storage device according to a third embodiment.

FIG. 13 is a cross-sectional view showing a semiconductor storage device according to a fourth embodiment.

### DETAILED DESCRIPTION

A semiconductor storage device according to an embodiment includes a substrate, a first word line, a second word line, a first channel, a first memory film, a second channel, a second memory film, a first insulating layer, a first source line, and a first drain line. The first word line extends in a first direction parallel to a surface of the substrate. The second word line is separated from the first word line in a second direction. The second direction is a thickness direction of the substrate. The second word line extends in the first direction. The first channel is aligned with the first word line in a third direction. The third direction crosses the first direction and the second direction. The first channel extends in the first direction. The first memory film is between the first word line and the first channel in the third direction. The first memory film extends in the first direction. The second channel is aligned with the second word line in the third direction. The second channel extends in the first direction. The second memory film is between the second word line and the second channel in the third direction. The second memory film extends in the first direction. The first insulating layer is between the first word line and the second word line in the second direction. The first insulating layer is between the first channel and the second channel in the second direction. The first source line is on a side opposite to the first word line with respect to the first channel in the third direction. The first source line extends in the second direction. The first drain line is separated from the first source line in the first direction. The first drain line is on a side opposite to the first word line with respect to the first channel in the third direction. The first drain line extends in the second direction.

Hereinafter, a semiconductor storage device according to the embodiment will be described with reference to the drawings. In the following description, components having the same or similar functions are denoted by the same reference signs. Also, duplicate description of the components may be omitted. “Parallel”, “perpendicular”, or “the same” may include a case of “substantially parallel”, “substantially perpendicular”, or “substantially the same”. “Connection” is not limited to a mechanical connection and may include an electrical connection. That is, “connection” is not limited to a case in which a plurality of elements are directly connected, and may include a case in which a plurality of elements are connected with another element interposed therebetween. A “ringed shape” is not limited to an annular shape, and includes a rectangular shape or a triangular shape.

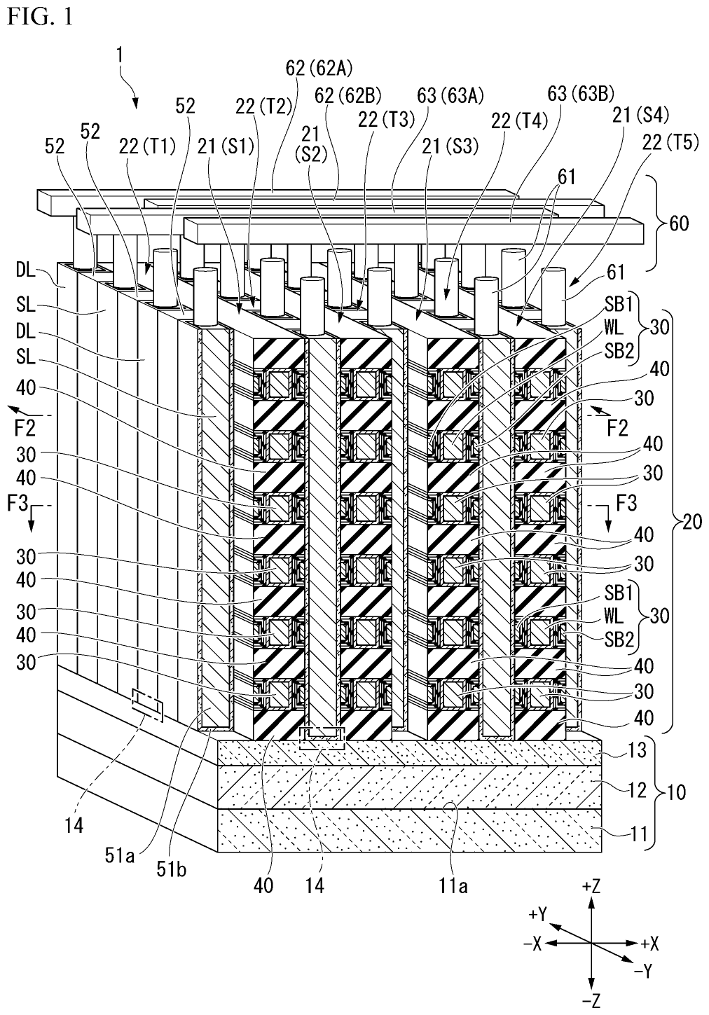

First, with reference to FIG. 1, a +X direction, a −X direction, a +Y direction, a −Y direction, a +Z direction, and a −Z direction will be defined. The +X direction, the −X direction, the +Y direction, and the −Y direction are directions along a surface 11a of a semiconductor substrate 11 to be described later. The +X direction is a direction in which a source line 62 and a drain line 63 of an upper structure 60 to be described later extend. The −X direction is a direction opposite to the +X direction. In a case in which the +X direction and the −X direction do not need to be distinguished from each other, the directions will be simply referred to as an “X direction”. The +Y direction and the −Y direction are directions intersecting (for example, perpendicular to) the X direction. That is, the +Y direction and the −Y direction are not parallel to the X direction. The +Y direction and the −Y direction cross the X direction. The +Y direction is a direction in which a word line WL to be described later extends. The −Y direction is a direction opposite to the +Y direction. In a case in which the +Y direction and the −Y direction do not need to be distinguished from each other, the directions will be simply referred to as a “Y direction”. The +Z direction and the −Z direction are directions intersecting (for example, perpendicular to) the X direction and the Y direction. The +Z direction and the −Z direction are a thickness direction of the semiconductor substrate 11. That is, the +Z direction and the −Z direction are not parallel to the X direction and the Y direction. The +Z direction and the −Z direction cross the X direction and the Y direction. The +Z direction is a direction from the semiconductor substrate 11 toward a multi-layered body 20 to be described later. The −Z direction is a direction opposite to the +Z direction. In a case in which the +Z direction and the −Z direction do not need to be distinguished from each other, the directions will be simply referred to as a “Z direction”. In the present specification, the “+Z direction” may be referred to as “upward” and the “−Z direction” may be referred to as “downward”. However, these expressions are for convenience only and do not define the direction of gravity. The Y direction is an example of a “first direction”. The Z direction is an example of a “second direction”. The X direction is an example of a “third direction”.

### First Embodiment

### 1. CONFIGURATION OF SEMICONDUCTOR STORAGE DEVICE

First, a configuration of a semiconductor storage device 1 according to a first embodiment will be described. In the drawings described below, an insulating part not related to the description may be omitted. Also, in some drawings, in order to make the drawings easier to see, only a part of a cross-sectional portion is shown by hatching.

FIG. 1 is a perspective cross-sectional view showing the semiconductor storage device 1. The semiconductor storage device 1 is, for example, a non-volatile semiconductor storage device. The semiconductor storage device 1 is a NOR type semiconductor storage device. The semiconductor storage device 1 includes, for example, a lower structure 10, a multi-layered body 20, and an upper structure 60.

### <1.1 Lower Structure>

The lower structure 10 includes, for example, a semiconductor substrate 11, a stopper layer 12, and a diffusion layer 13.

The semiconductor substrate 11 is a substrate serving as a base part of the semiconductor storage device 1. At least a part of the semiconductor substrate 11 has a plate shape in the X direction and the Y direction. The semiconductor substrate 11 has a surface 11a facing the multi-layered body 20 to be described later. The semiconductor substrate 11 is formed of, for example, a semiconductor material containing silicon (Si). The semiconductor substrate 11 is an example of a “substrate”.

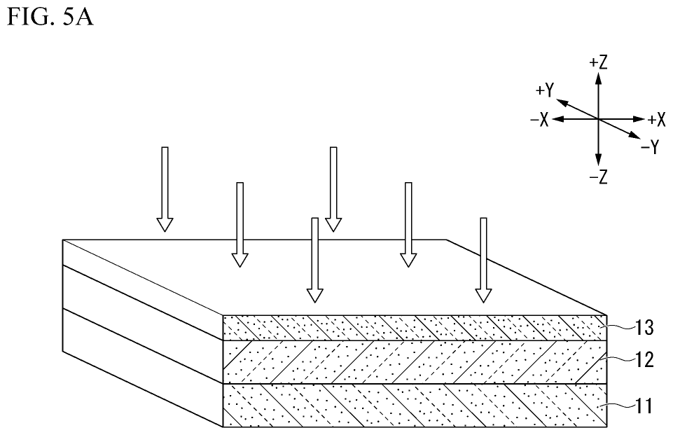

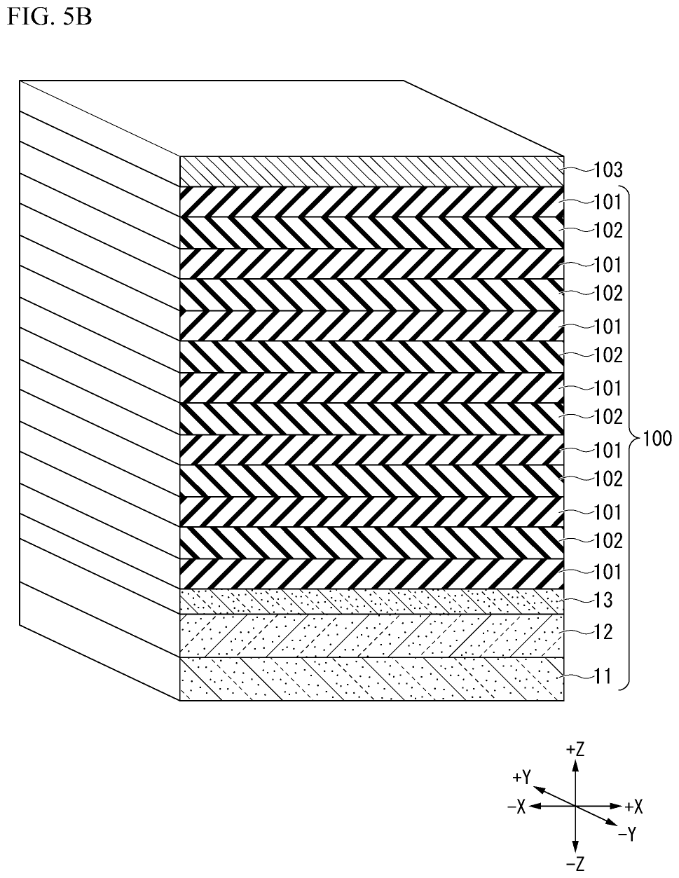

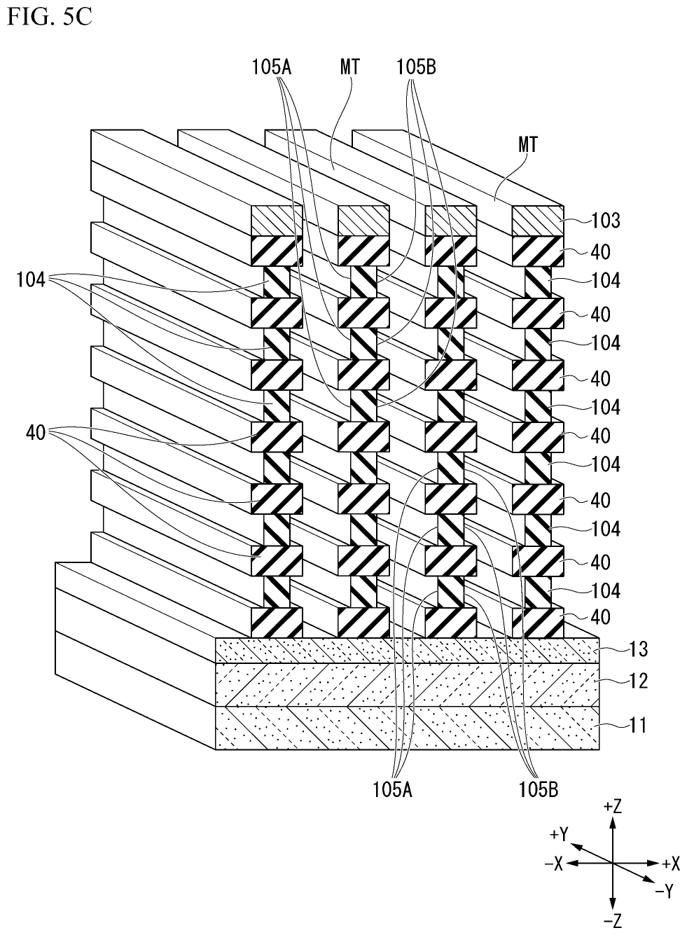

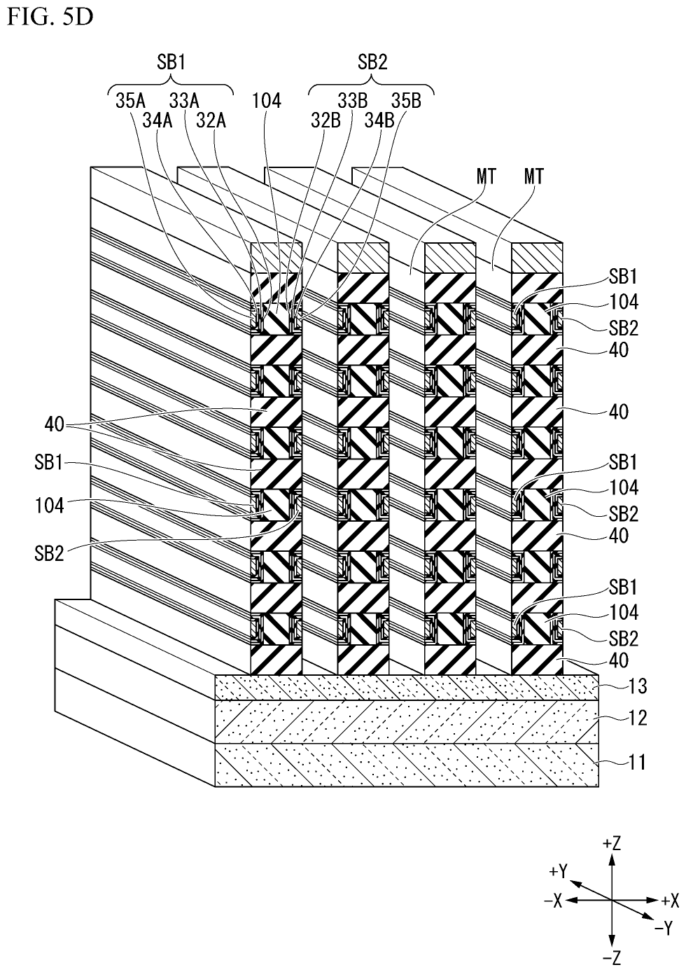

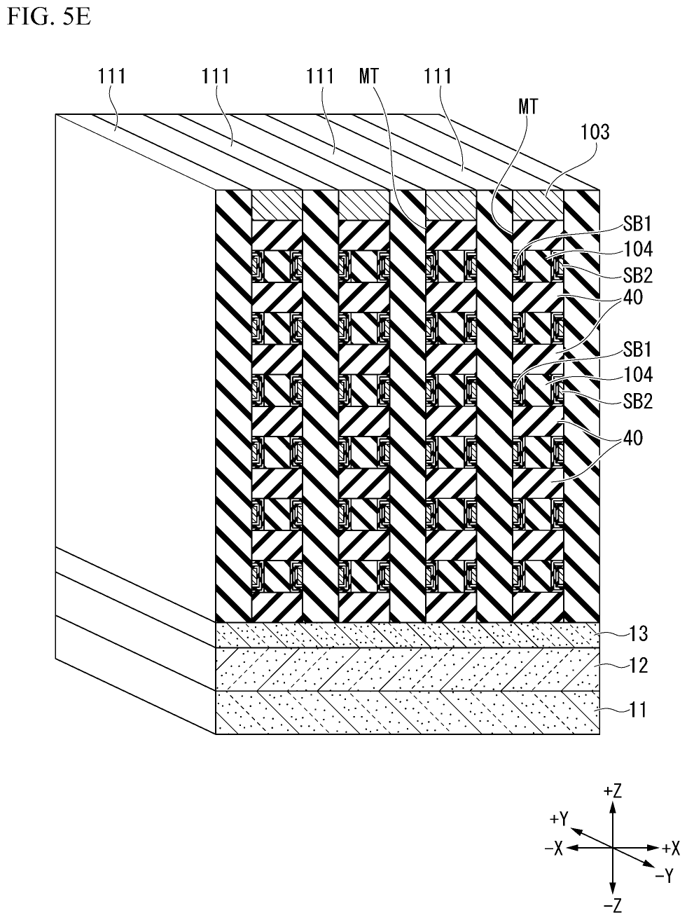

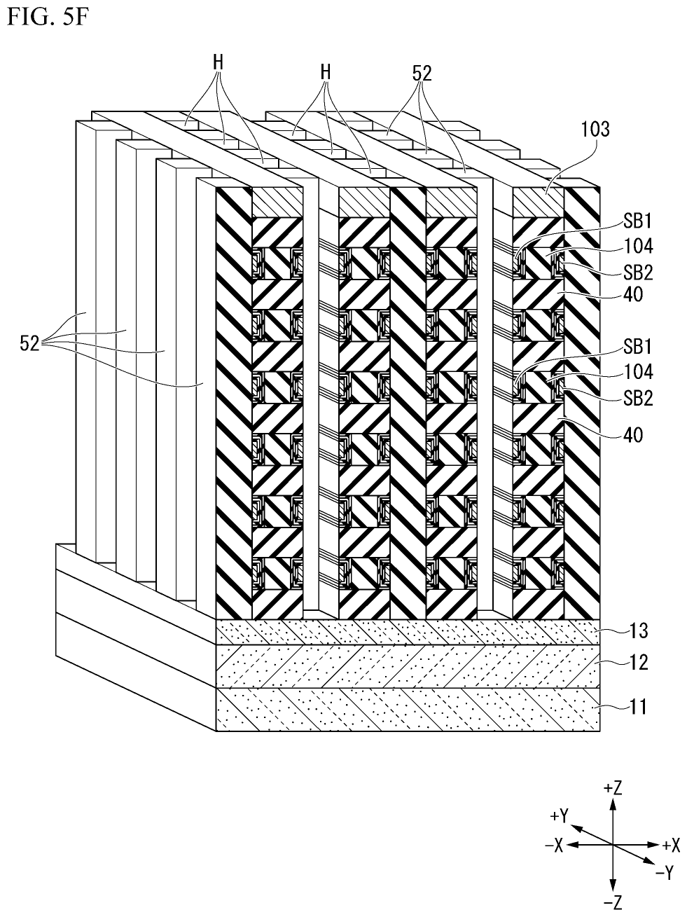

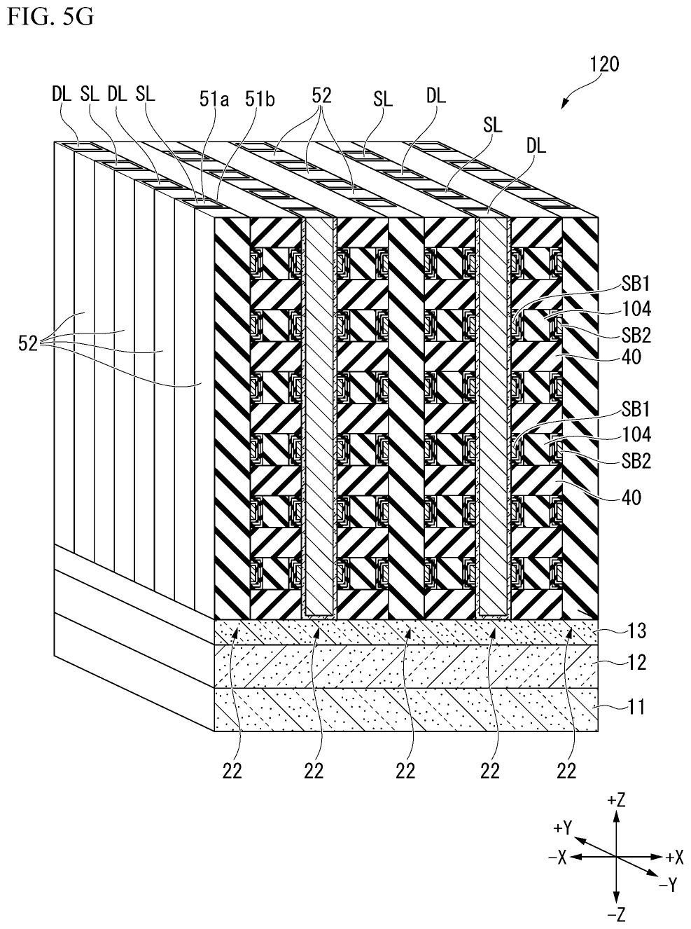

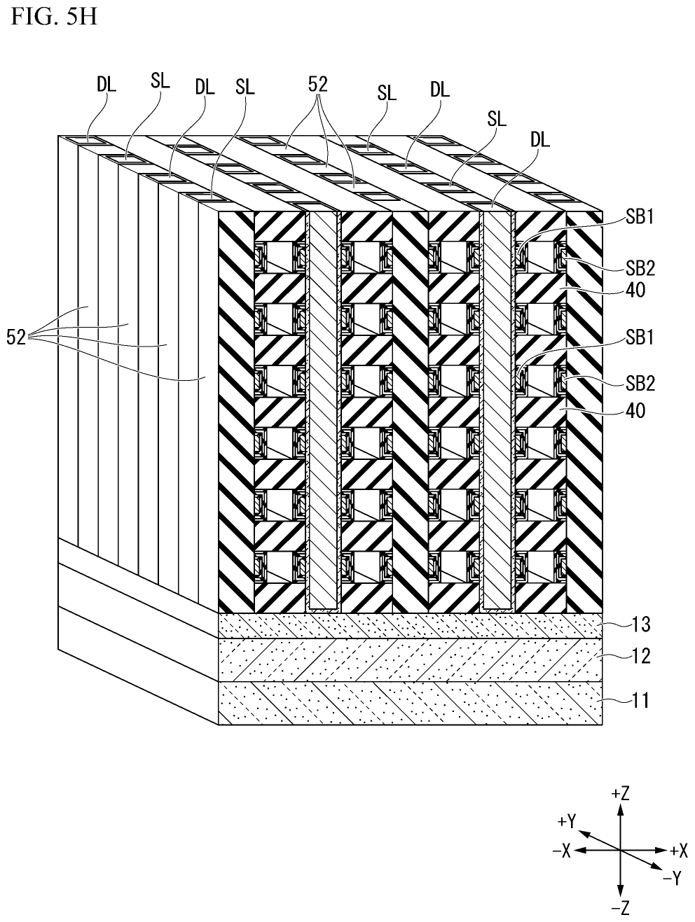

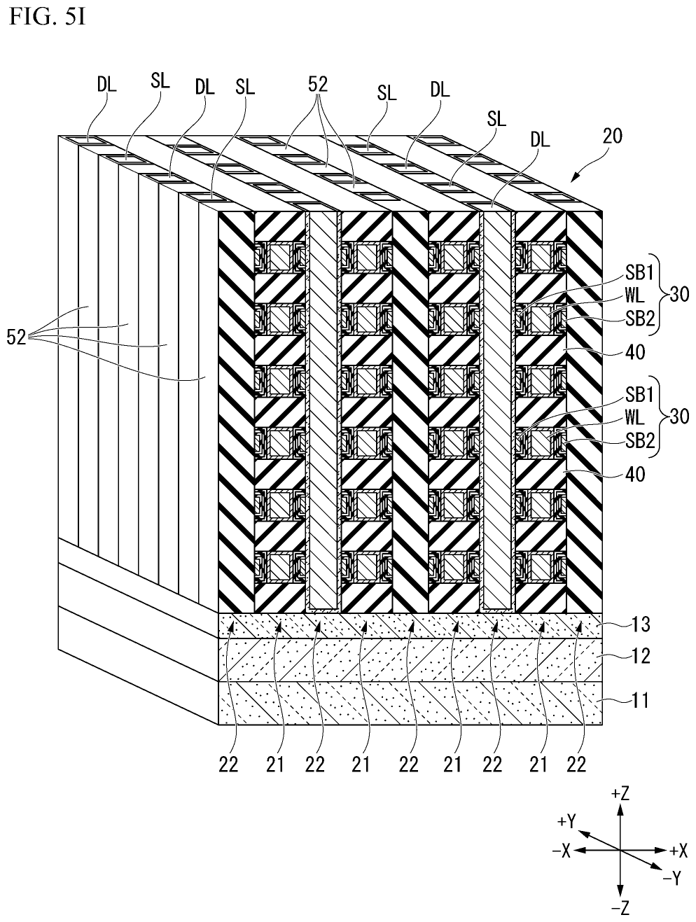

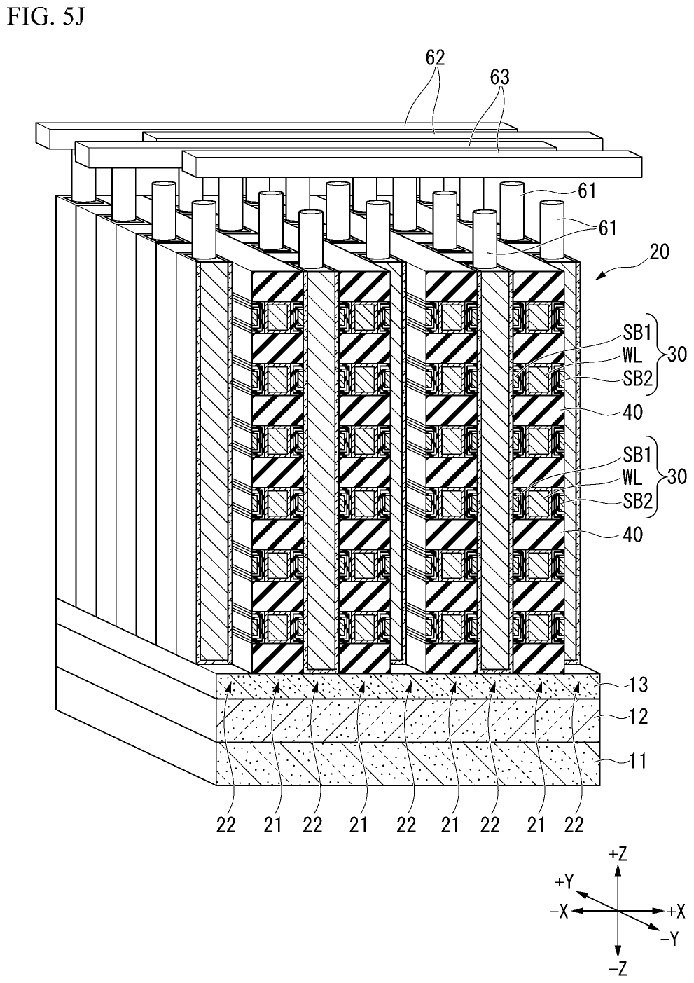

The stopper layer 12 is provided on the semiconductor substrate 11. The stopper layer 12 has a layer shape in the X direction and the Y direction. The stopper layer 12 is a layer that suppresses deep digging of a trench MT (see FIG. 5C) in a manufacturing process of the semiconductor storage device 1 to be described later. The stopper layer 12 is formed of, for example, a semiconductor material such as polysilicon (Poly-Si).

The diffusion layer 13 is provided as a part of an upper surface portion of the stopper layer 12. The diffusion layer 13 has a layer shape in the X direction and the Y direction. The diffusion layer 13 is a layer that secures an electrical withstand voltage between a source line SL and a drain line DL to be described later. The diffusion layer 13 contains impurities different from those of the source line SL and the drain line DL. The diffusion layer 13 has a conductive type different from that of the source line SL and the drain line DL. In the embodiment, the source line SL and the drain line DL contain impurities serving as donors and have a conductive type of n-type (for example, n+ type). On the other hand, the diffusion layer 13 contains impurities serving as acceptors, and the diffusion layer 13 has a conductive type of p-type (for example, p− type). The acceptors may be, for example, boron (B), but are not limited thereto. Furthermore, the stopper layer 12 may be omitted, and the diffusion layer 13 may be provided as a part of an upper surface portion of the semiconductor substrate 11. In this case, an upper surface of the diffusion layer 13 is the surface 11a of the semiconductor substrate 11.

### <1.2 Multi-Layered Body>

Next, the multi-layered body 20 will be described. The multi-layered body 20 is provided on the lower structure 10. The multi-layered body 20 includes a plurality of first structural parts 21 and a plurality of second structural parts 22. The plurality of the first structural parts 21 and the plurality of the second structural parts 22 are alternately disposed one by one in the X direction.

### <1.2.1 First Structural Part>

First, the first structural part 21 will be described. The plurality of the first structural parts 21 are separated from each other in the X direction. The plurality of the first structural parts 21 extend in the Y direction parallel to each other. Hereinafter, the plurality of the first structural parts 21 having different positions in the X direction are referred to as a plurality of columns S (first column S1, second column S2, third column S3, . . . ).

Each of the plurality of the first structural parts 21 includes a plurality of functional layers 30 and a plurality of insulating layers 40. The plurality of the functional layers 30 and the plurality of the insulating layers 40 are alternately stacked one layer by one layer in the Z direction. Six functional layers 30 and seven insulating layers 40 are shown in FIG. 1, but in practice, a larger number of functional layers 30 and insulating layers 40 are stacked.

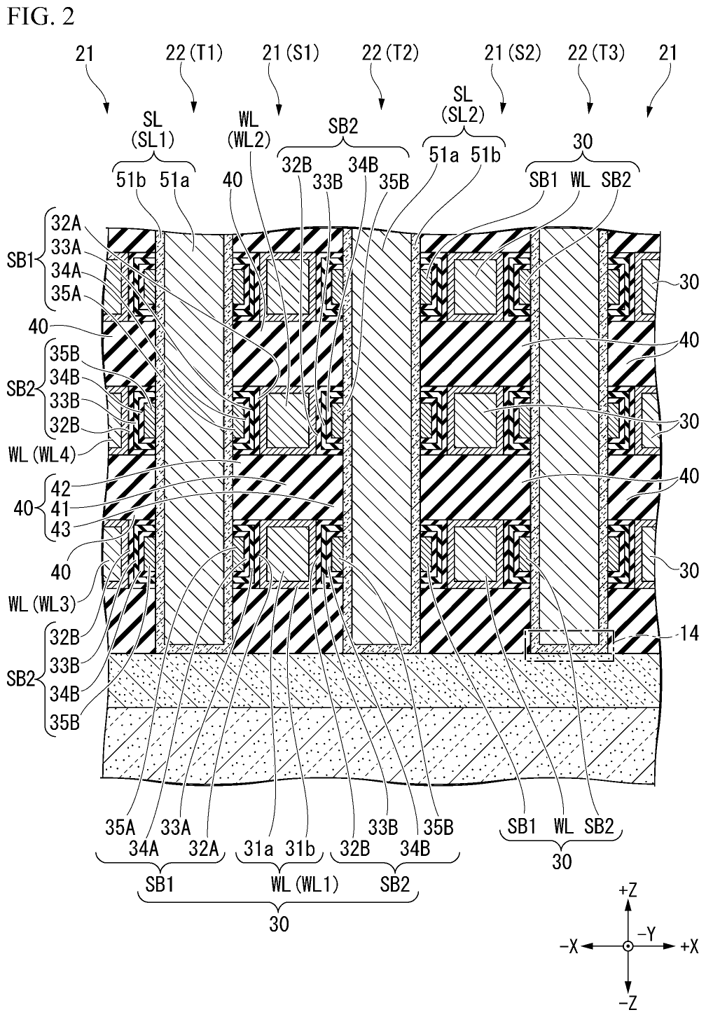

FIG. 2 is a cross-sectional view taken along line F2-F2 of the semiconductor storage device 1 shown in FIG. 1. FIG. 2 shows a cross section taken along a section line passing through a plurality of source lines SL to be described later for convenience of description. Each of the functional layers 30 has a layer shape in the X direction and the Y direction. The functional layer 30 includes, for example, a word line WL, a first side structure SB1 positioned on the side in the −X direction of the word line WL, and a second side structure SB2 positioned on the side in the +X direction of the word line WL.

The word line WL extends linearly in the Y direction. The word line WL is, for example, an interconnection to which a voltage is applied at the time of writing a data value or reading a data value with respect to a memory cell MC to be described later. In the embodiment, a plurality of word lines WL are separated one by one so that voltages can be applied thereto independently of each other. The word line WL includes, for example, a main body portion 31a and a barrier metal film 31b. The main body portion 31a is provided inside the barrier metal film 31b to form a main part of the word line WL. The main body portion 31a is formed of, for example, tungsten (W) or a conductive material such as polysilicon (Poly-Si) doped with impurities. The barrier metal film 31b is provided on a surface of the word line WL. The barrier metal film 31b is a film that suppresses diffusion of the material contained in the main body portion 31a. The barrier metal film 31b is formed of, for example, titanium nitride (TiN).

Next, the first side structure SB 1 will be described. The first side structure SB1 includes, for example, a block insulating film 32A, a memory film 33A, a tunnel insulating film 34A, and a channel 35A.

The block insulating film 32A is positioned on the side in the −X direction with respect to the word line WL included in the same functional layer 30 (hereinafter referred to as “specific word line WL”). The block insulating film 32A is an insulating film that suppresses back tunneling. Back tunneling is a phenomenon in which electric charges return from the word line WL to the memory film 33A. The block insulating film 32A is provided, for example, along a side surface of the specific word line WL on the side in the −X direction, an upper surface of the insulating layer 40 just below, and a lower surface of the insulating layer 40 right above. The block insulating film 32A extends linearly in the Y direction parallel to the side surface of the word line WL. The block insulating film 32A is formed of, for example, a silicon oxide film, a metal oxide film, and a multi-layered structure film in which a plurality of insulating films are stacked. An example of the metal oxide is aluminum oxide (Al₂O₃). The block insulating film 32A may contain a high dielectric constant material (High-k material) such as silicon nitride (SiN) or hafnium oxide (HfO).

The memory film 33A is positioned on the side in the −X direction with respect to the specific word line WL. The memory film 33A is a functional film capable of storing information on the basis of a state of the memory film 33A. The memory film 33A stores information on the basis of, for example, a voltage applied to the specific word line WL. The memory film 33A is, for example, a charge trap film capable of accumulating charges in crystal defects. The charge trap film is formed of, for example, silicon nitride (Si₃N₄). The block insulating film 33A is provided, for example, along a side surface of the block insulating film 32A on the side in the −X direction, an upper surface of a lower portion of the block insulating film 32A, and a lower surface of an upper portion of the block insulating film 32A. The memory film 33A extends linearly in the Y direction parallel to the side surface of the block insulating film 32A.

The tunnel insulating film 34A is positioned on the side in the −X direction with respect to the specific word line WL. The tunnel insulating film 34A is a potential barrier between the memory film 33A and the channel 35A. The tunnel insulating film 34A is provided, for example, along a side surface of the memory film 33A on the side in the −X direction, an upper surface of a lower portion of the memory film 33A, and a lower surface of an upper portion of the memory film 33A. The tunnel insulating film 34A extends linearly in the Y direction parallel to the side surface of the memory film 33A. The tunnel insulating film 34A is formed of an insulating material containing silicon oxide (SiO₂) or silicon oxide (SiO₂) and silicon nitride (SiN).

The channel 35A is positioned on the side in the −X direction with respect to the specific word line WL. The channel 35A is, for example, an interconnection through which a current flows at the time of writing a data value or reading a data value with respect to the memory cell MC to be described later. A current flows in the channel 35A between one set of the source line SL and the drain line DL. The channel 35A is provided, for example, along a side surface of the tunnel insulating film 34A on the side in the −X direction, an upper surface of a lower portion of the tunnel insulating film 34A, and a lower surface of an upper portion of the tunnel insulating film 34A. The channel 35A extends linearly in the Y direction parallel to the side surface of the tunnel insulating film 34A. The channel 35A is formed of, for example, a semiconductor material such as amorphous silicon (a-Si).

Next, the second side structure SB2 will be described. The second side structure SB2 includes, for example, a block insulating film 32B, a memory film 33B, a tunnel insulating film 34B, and a channel 35B. Furthermore, details of components of the second side structure SB2 are the same as details of components of the first side structure SB1 described above. That is, for details of the components of the second side structure SB2, the “−X direction”, the “first side structure SB1”, the “block insulating film 32A”, the “memory film 33A”, the “tunnel insulating film 34A”, and the “channel 35A” in the above-described description regarding the first side structure SB1 may be read as the “+X direction”, the “second side structure SB2”, the “block insulating film 32B”, the “memory film 33B”, the “tunnel insulating film 34B”, and the “channel 35B”. Hereinafter, in a case in which the “memory film 33A” and the “memory film 33B” do not need to be distinguished from each other, they will be simply referred to as “memory film 33” and in a case in which the “channel 35A” and the “channel 35B” do not need to be distinguished from each other, they will be simply referred to as “channel 35”.

Next, the insulating layer 40 will be described. The insulating layer 40 has a layer shape in the X direction and the Y direction. The insulating layer 40 is formed of an insulating material such as silicon oxide (SiO₂). The insulating layer 40 is provided between the plurality of the functional layers 30 aligned in the Z direction, and electrically insulates the plurality of the functional layers 30 aligned in the Z direction from each other.

In the embodiment, the insulating layer 40 includes a first portion 41, a second portion 42, and a third portion 43. The first portion 41 is positioned between the word line WL included in the functional layer 30 just below the insulating layer 40 and the word line WL included in the functional layer 30 right above the insulating layer 40 in the Z direction. Therefore, the first portion 41 electrically insulates between the word line WL included in the functional layer 30 just below the insulating layer 40 and the word line WL included in the functional layer 30 right above the insulating layer 40.

The second portion 42 is positioned on the side in the −X direction with respect to the first portion 41. The second portion 42 is provided between the first side structure SB1 included in the functional layer 30 just below the insulating layer 40 and the first side structure SB1 included in the functional layer 30 right above the insulating layer 40 in the Z direction. Each first side structure SM includes the block insulating film 32A, the memory film 33A, the tunnel insulating film 34A, and the channel 35A. Therefore, the second portion 42 electrically insulates between the first side structure SB1 included in the functional layer 30 just below the insulating layer 40 and the first side structure SB1 included in the functional layer 30 right above the insulating layer 40.

The third portion 43 is positioned on the side in the +X direction with respect to the first portion 41. The third portion 43 is provided between the second side structure SB2 included in the functional layer 30 just below the insulating layer 40 and the second side structure SB2 included in the functional layer 30 right above the insulating layer 40 in the Z direction. Each second side structure SB2 includes the block insulating film 32B, the memory film 33B, the tunnel insulating film 34B, and the channel 35B. Therefore, the third portion 43 electrically insulates between the second side structure SB2 included in the functional layer 30 just below the insulating layer 40 and the second side structure SB2 included in the functional layer 30 right above the insulating layer 40.

### <1.2.2 Second Structural Part>

Next, returning to FIG. 1, the second structural part 22 will be described. The plurality of the second structural parts 22 are separated from each other in the X direction. The plurality of the second structural parts 22 extend in the Y direction parallel to each other. Each of the plurality of the second structural parts 22 includes the plurality of the source lines SL, a plurality of drain lines DL, and a plurality of insulators 52.

The plurality of the source lines SL and the plurality of the drain lines DL are alternately disposed one by one at intervals in the Y direction. Each of the source lines SL and the drain lines DL extends in the Z direction and penetrates the multi-layered body 20 in the Z direction. That is, each of the source lines SL and the drain lines DL extends from above the uppermost functional layer 30 in the plurality of the functional layers 30 aligned in the Z direction to a lateral side of or below the lowermost functional layer 30.

Each of the source lines SL and the drain lines DL includes, for example, a main body portion 51a and a surface layer portion 51b. The main body portion 51a is provided inside the surface layer portion 51b and forms a main part of the source line SL or the drain line DL. The main body portion 51a is formed of, for example, a metal material or a conductive material such as polysilicon (Poly-Si) doped with impurities. In the embodiment, the main body portion 51a is formed of a metal material such as tungsten (W). The surface layer portion 51b is provided on a surface of the source line SL or the drain line DL. The surface layer portion 51b is formed in an annular shape that surrounds the main body portion 51a from the +X direction, the −X direction, the +Y direction, and the −Y direction. A part of the surface layer portion 51b covers a lower surface of the main body portion 51a. The part of the surface layer portion 51b is positioned between the main body portion 51a and the diffusion layer 13. In the embodiment, the surface layer portion 51b contains impurities serving as donors, and the surface layer portion 51b has a conductive type of n-type (for example, n+ type). Lower end portions of the source lines SL and the drain lines DL are in contact with the diffusion layer 13 of the lower structure 10. Therefore, a PN junction part 14 having a depletion layer and improving an electrical withstand voltage is formed between each of the source line SL and the plurality of the drain lines DL, and the semiconductor substrate 11.

The plurality of the source lines SL and the plurality of the drain lines DL included in one of the second structural parts 22 are disposed between two first structural parts 21 adjacent to each other in the X direction. Hereinafter, the plurality of the second structural parts 22 having different positions in the X direction are referred to as a plurality of columns T (first column Tl, second column T2, third column T3, . . . ).

The plurality of the source lines SL and the plurality of the drain lines DL included in the first column T1 are positioned on the side in the −X direction with respect to the plurality of the functional layers 30 included in the first column S1. The plurality of the source lines SL and the plurality of the drain lines DL included in the first column T1 are in contact with the channels 35A of the plurality of the functional layers 30 included in the first column S1 from the side in the −X direction. The plurality of the source lines SL and the plurality of the drain lines DL included in the first column T1 are electrically connected to the channels 35A of the plurality of the functional layers 30. Therefore, the plurality of the source lines SL and the plurality of the drain lines DL included in the first column T1 function as sources and drains for the channels 35A of the plurality of the functional layers 30 included in the first column S1. That is, in the first column T1, one source line SL and one drain line DL adjacent to the source line SL can be electrically connected via the channel 35A. In the embodiment, the plurality of the source lines SL and the plurality of the drain lines DL included in the first column T1 are in contact with the plurality of the insulating layers 40 included in the first column S1 from the side in the −X direction.

The plurality of the source lines SL and the plurality of the drain lines DL included in the second column T2 are positioned between the plurality of the functional layers 30 included in the first column S1 and the plurality of the functional layers 30 included in the second column S2 in the X direction. The plurality of the source lines SL and the plurality of the drain lines DL included in the second column T2 are in contact with the channels 35B of the plurality of the functional layers 30 included in the first column T1 from the side in the +X direction. The plurality of the source lines SL and the plurality of the drain lines DL included in the second column T2 are electrically connected to the channels 35B of the plurality of the functional layers 30. Therefore, the plurality of the source lines SL and the plurality of the drain lines DL included in the second column T2 function as sources and drains for the channels 35B of the plurality of the functional layers 30 included in the first column T1. That is, in the second column T2, one source line SL and one drain line DL adjacent to the source line SL can be electrically connected via the channel 35B. In the embodiment, the plurality of the source lines SL and the plurality of the drain lines DL included in the second column T2 are in contact with the plurality of the insulating layers 40 included in the first column S1 from the side in the +X direction.

Furthermore, the plurality of the source lines SL and the plurality of the drain lines DL included in the second column T2 are in contact with the channels 35A of the plurality of the functional layers 30 included in the second column S2 from the side in the −X direction. The plurality of the source lines SL and the plurality of the drain lines DL included in the second column T2 are electrically connected to the channels 35A of the plurality of the functional layers 30. Therefore, the plurality of the source lines SL and the plurality of the drain lines DL included in the second column T2 function as sources and drains for the channels 35A of the plurality of the functional layers 30 included in the second column S2. That is, in the second column T2, one source line SL and one drain line DL adjacent to the source line SL can be electrically connected via the channel 35A. The plurality of the source lines SL and the plurality of the drain lines DL included in the second column T2 are in contact with the plurality of the insulating layers 40 included in the second column S2 from the side in the −X direction. The plurality of the source lines SL and the plurality of the drain lines DL belonging to the third column T3 and the subsequent columns T also are configured in the same manner as the plurality of the source lines SL and the plurality of the drain lines DL included in the second column T2.

Next, the insulator 52 will be described.

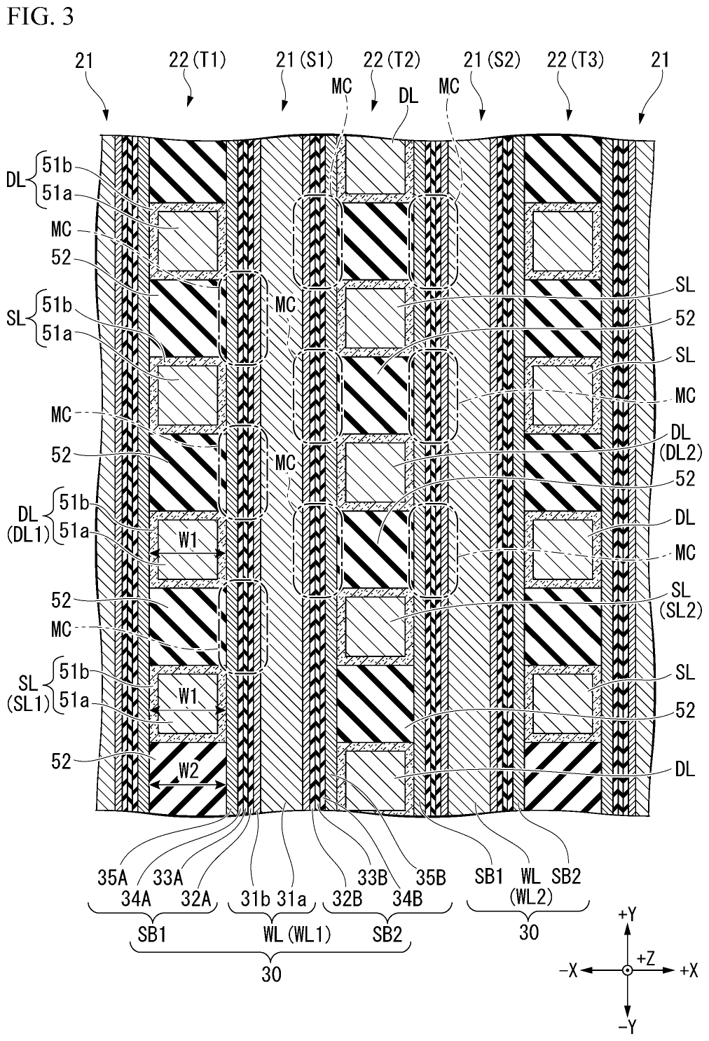

FIG. 3 is a cross-sectional view taken along line F3-F3 of a part of the semiconductor storage device 1 shown in FIG. 1. The insulator 52 is provided between the source line SL and the drain line DL adjacent thereto in the Y direction. A width W2 of the insulator 52 in the X direction is the same as a width W1 of the source line SL or the drain line DL in the X direction. The insulator 52 extends in the Z direction over the entire length (total height) of the source line SL and the drain line DL. The insulator 52 is provided between the source line SL and the drain line DL adjacent thereto in the Y direction, and electrically insulates between the source line SL and the drain line DL in the Y direction. For example, the insulator 52 is provided between one set of the source line SL and the drain line DL which are electrically connected via the channel 35. The insulator 52 electrically insulates between the source line SL and the drain line DL in the Y direction.

In the embodiment, the plurality of the source lines SL and the plurality of the drain lines DL included in the even-numbered column T (T2, T4, . . . ) are disposed to be shifted in the Y direction with respect to the plurality of the source lines SL and the plurality of the drain lines DL included in the odd-numbered column T (T1, T3, . . . ).

With the above-described configuration, the semiconductor storage device 1 includes a plurality of memory cells MC. That is, in the first side structure SB1 and the second side structure SB2, a region positioned between one set of source line SL and the drain line DL electrically connected to each other functions as the memory cell MC. The memory cell MC is, for example, a metal-Al-nitride-oxide-silicon (MANOS) type memory cell. The plurality of the memory cells MC are three-dimensionally disposed at intervals in the X direction, the Y direction, and the Z direction.

### <1.4 Upper Structure>

Next, returning to FIG. 1, the upper structure 60 will be described.

The upper structure 60 includes, for example, a plurality of contacts 61, a plurality of source lines 62, and a plurality of drain lines 63. The plurality of the contacts 61 are, for example, columnar or conical conductor parts. The plurality of the contacts 61 are disposed above the multi-layered body 20. The plurality of the contacts 61 extend in the Z direction. The plurality of the contacts 61 are disposed to correspond to the plurality of the source lines 62 and the plurality of the drain lines 63. The plurality of the contacts 61 are connected to the plurality of the source lines 62 and the plurality of the drain lines 63 in one-to-one correspondence.

The plurality of the source lines 62 are separated from each other in the Y direction. The plurality of the source lines 62 extend in the X direction. The plurality of the source lines 62 include a plurality of source lines 62A (only one is shown in FIG. 1) and a plurality of source lines 62B (only one is shown in FIG. 1). The source line 62A is disposed above the contacts 61 connected to the plurality of the source lines SL included in the odd-numbered column T (T1, T3, . . . ). The source line 62A is commonly connected to the plurality of the source lines SL included in the odd-numbered column T via the contacts 61. On the other hand, the source line 62B is disposed above the contacts 61 connected to the plurality of the source lines SL included in the even-numbered column T (T2, T4, . . . ). The source line 62B is commonly connected to the plurality of the source lines SL included in the even-numbered column T via the contacts 61.

The plurality of the drain lines 63 are separated from each other in the Y direction. The plurality of the drain lines 63 extend in the X direction. The plurality of the drain lines 63 includes a plurality of drain lines 63A (only one is shown in FIG. 1) and a plurality of drain lines 63B (only one is shown in FIG. 1). The drain line 63A is disposed above the contacts 61 connected to the plurality of the drain lines DL included in the odd-numbered column T (T1, T3, . . . ). The drain line 63A is commonly connected to the plurality of the drain lines DL included in the odd-numbered column T via the contacts 61. On the other hand, the drain line 63B is disposed above the contacts 61 connected to the plurality of the drain lines DL included in the even-numbered column T (T2, T4, . . . ). The drain line 63B is commonly connected to the plurality of the drain lines DL included in the even-numbered column T via the contacts 61.

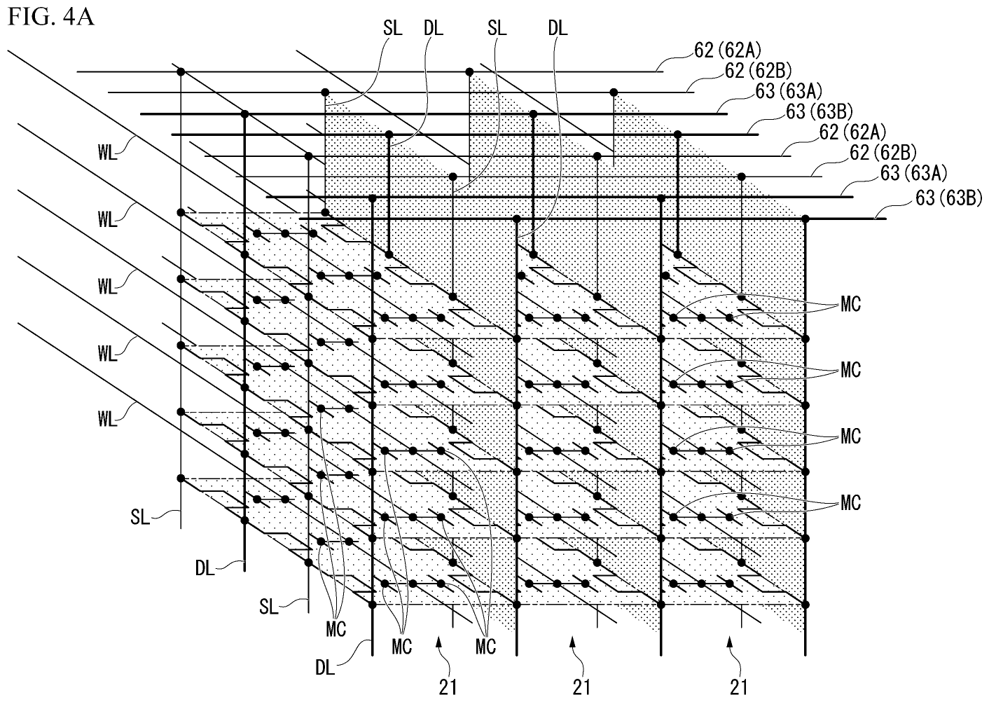

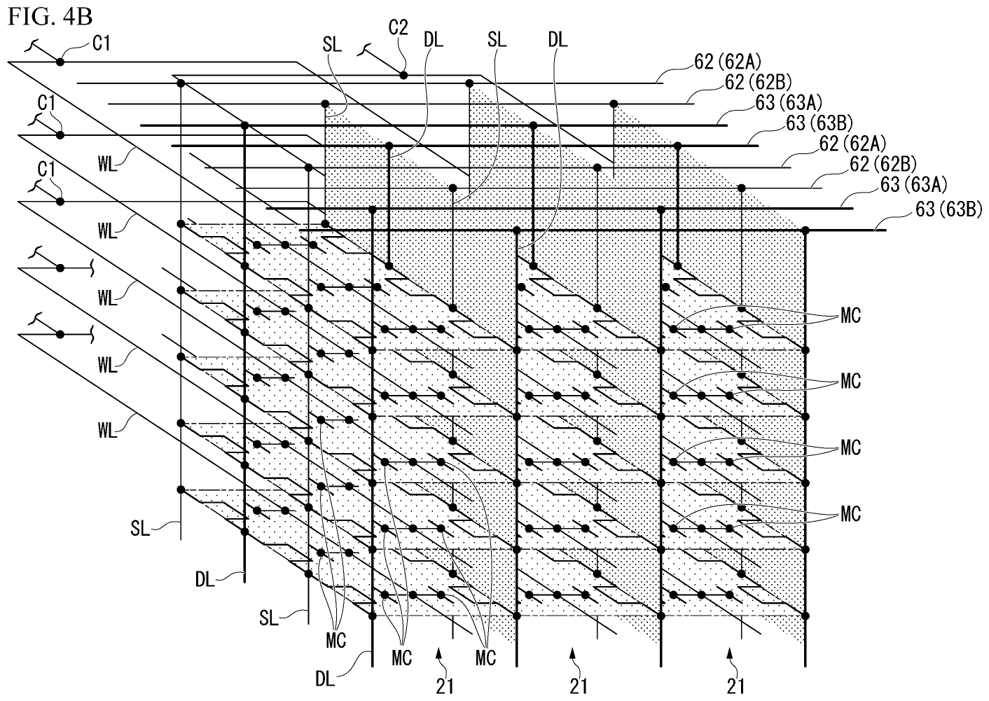

FIG. 4A is a diagram showing an equivalent circuit of the semiconductor storage device 1. As shown in FIG. 4A, the plurality of the memory cells MC are three-dimensionally disposed at intervals in the X direction, the Y direction, and the Z direction. Then, one memory cell MC can be selected by, for example, a combination of the word line WL, the source line SL, and the drain line DL. In the semiconductor storage device 1, any memory cell MC can be randomly accessed.

FIG. 4B is a diagram showing an equivalent circuit of a modified example of the semiconductor storage device 1. In the modified example shown in FIG. 4B, among the plurality of the word lines WL having the same position in the Z direction (that is, the plurality of the word lines WL aligned in the X direction), the plurality of the word lines WL included in the odd-numbered columns S1, S3, S5, . . . of the plurality of the columns S are connected to each other via a connection part C1, and a voltage can be collectively applied. Also, among the plurality of the word lines WL having the same position in the Z direction (that is, the plurality of the word lines WL aligned in the X direction), the plurality of the word lines WL included in the even-numbered columns S2, S4, S6, . . . of the plurality of the columns S are connected to each other via a connection part C2, and a voltage can be collectively applied. On the other hand, the plurality of the source lines SL and the plurality of the drain lines DL corresponding to the plurality of the word lines WL connected to each other are separated one by one so that voltages can be applied thereto independently of each other. The plurality of the source lines SL or the plurality of the drain lines DL corresponding to the plurality of the word lines WL connected to each other may be separated one by one so that voltages can be applied thereto independently of each other. According to such a configuration, it may be possible to simplify an interconnection layout for the word lines WL and reduce a size of the semiconductor storage device 1. Furthermore, the plurality of the word lines WL having the same position in the Z direction may be connected every three lines instead of being connected every other line.

### 2. OPERATION EXAMPLE

Next, an operation example of the semiconductor storage device 1 will be described.

In the semiconductor storage device 1, a memory cell MC can be optionally selected as a data value to be written or a data value to be read by, for example, a combination of the word line WL, the source line SL, and the drain line DL. For example, in a write operation, a peripheral circuit of the semiconductor storage device 1 applies a voltage to the drain line DL (or source line SL) corresponding to a memory cell MC to be written, and applies a programming pulse as a write voltage to the word line WL corresponding to the memory cell MC to be written. The programming pulse refers to a pulse in which a voltage gradually increases with each cycle. Therefore, a current flows in a region between the source line SL and the drain line DL corresponding to the memory cell MC to be written in the channel 35, and electric charges are accumulated in the memory cell MC to be written. Therefore, the data value is stored in the memory cell MC.

On the other hand, in a read operation, the sense amplifier circuit of the semiconductor storage device 1 pre-charges a power supply potential Vcc to the drain line DL corresponding to a memory cell MC to be read. The peripheral circuit of the semiconductor storage device 1 sequentially applies a plurality of types of determination potentials (threshold determination voltage) for determining a threshold voltage of the memory cell MC to the word line WL corresponding to the memory cell MC to be read. The sense amplifier circuit described above detects whether or not each type of determination voltages is applied when the charge stored by the pre-charge flows out to the source line SL (or drain line DL) and thereby determines a data value stored in the memory cell MC to be read.

### 3. METHOD OF MANUFACTURING SEMICONDUCTOR STORAGE DEVICE

Next, a method of manufacturing the semiconductor storage device 1 will be described. FIGS. 5A to 5J are perspective cross-sectional views for explaining a method of manufacturing the semiconductor storage device 1.

As shown in FIG. 5A, the diffusion layer 13 is formed on an upper surface of the stopper layer 12 (or the semiconductor substrate 11). The diffusion layer 13 is formed, for example, by the upper surface of the stopper layer 12 (or the semiconductor substrate 11) being doped with impurities and subjected to an annealing treatment.

Next, as shown in FIG. 5B, an insulating layer 101 formed of silicon oxide (SiO₂) and an insulating layer 102 formed of silicon nitride (SiN) are alternately stacked on the diffusion layer 13. Therefore, an intermediate structure 100 is formed. The insulating layer 102 is a sacrificial layer that is replaced by the plurality of the functional layers 30 in a subsequent process. Then, a stopper layer 103 as a mask is provided on the intermediate structure 100. The stopper layer 103 is formed of, for example, amorphous silicon (a-Si), a metal material, or the like.

Next, as shown in FIG. 5C, a plurality of trenches MT are formed by etching using the stopper layer 103. Each trench MT is a groove dug in the Z direction and extending in the Y direction. Therefore, the insulating layer 101 becomes the plurality of the separated insulating layers 40 in the X direction, and the insulating layer 102 becomes a plurality of separated insulating layers 104 in the X direction. Next, an etching solution (for example, hot phosphoric acid (H₃PO₄)) is supplied to each of the trenches MT to remove both end portions of the insulating layer 104 in the X direction by etching. Therefore, a side surface of the insulating layer 104 in the −X direction forms a first recess 105A recessed in the +X direction with respect to a side surface of the insulating layer 40 in the −X direction. Similarly, a side surface of the insulating layer 104 in the +X direction forms a second recess 105B recessed in the −X direction with respect to a side surface of the insulating layer 40 in the +X direction.

Next, as shown in FIG. 5D, materials serving as sources of the block insulating film, the memory film, the tunnel insulating film, and the channel are supplied to an inner surface of the trench MT. Then, an unnecessary portion is removed by etching. In the embodiment, after the insides of the first recess 105A and the second recess 105B are closed by the material of the channel, etch back is performed only on the material of the channel, or up to the material of the channel, the material of the tunnel insulating film, and the material of the memory film using a choline-based wet solution to form the channel 35 only inside the first recess 105A and the second recess 105B. Therefore, the block insulating film 32A, the memory film 33A, the tunnel insulating film 34A, and the channel 35A are formed on an inner surface of the first recess 105A, and the block insulating film 32B, the memory film 33B, the tunnel insulating film 34B, and the channel 35B are formed on an inner surface of the second recess 105B. Therefore, the plurality of the first structural parts 21 are formed.

Next, as shown in FIG. 5E, the trench MT is filled with an insulating material such as silicon oxide (SiO₂), and an insulator 111 is formed inside the trench MT. The insulator 111 has a plate shape in the Y direction and the Z direction.

Next, as shown in FIG. 5F, a hole H is formed by etching at a position in which the source line SL and the drain line DL are formed in a subsequent process. The hole H is a hole extending in the Z direction. Next, as shown in FIG. 5G, the source line SL or the drain line DL is formed inside the hole H. For example, the surface layer portion 51b containing polyvinyl (Poly-Si) doped with impurities is formed on an inner surface of the hole H. Next, a metal material is supplied to the inside of the surface layer portion 51b, and thereby the main body portion 51a is formed. Therefore, an intermediate structure 120 is obtained.

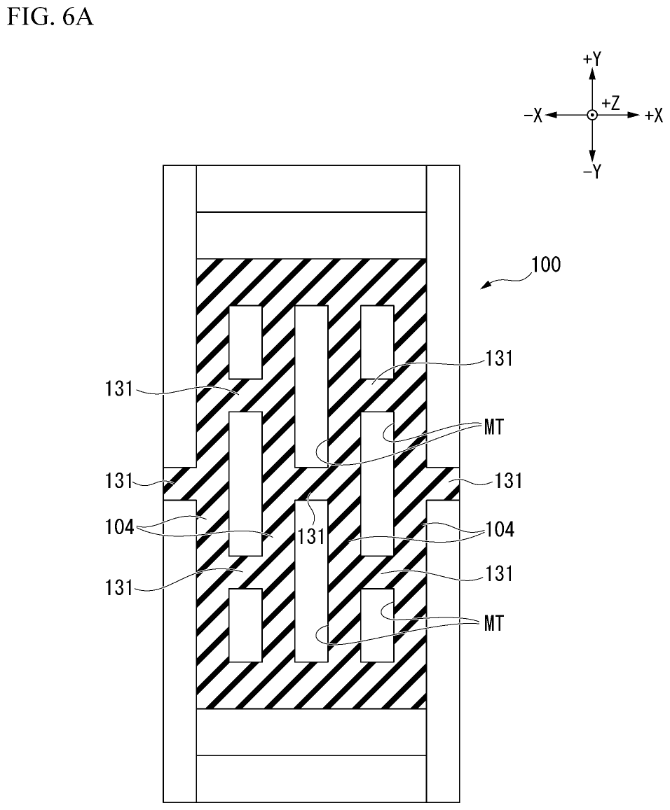

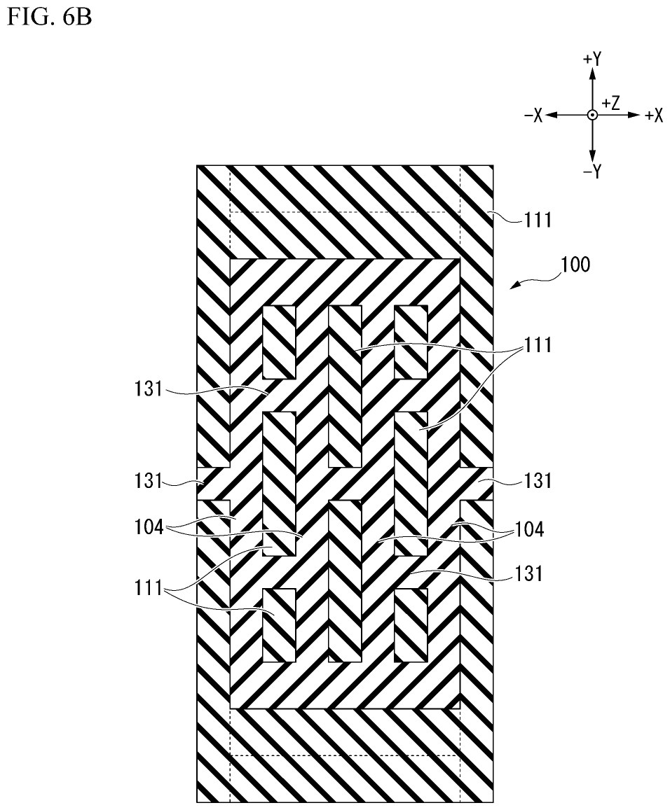

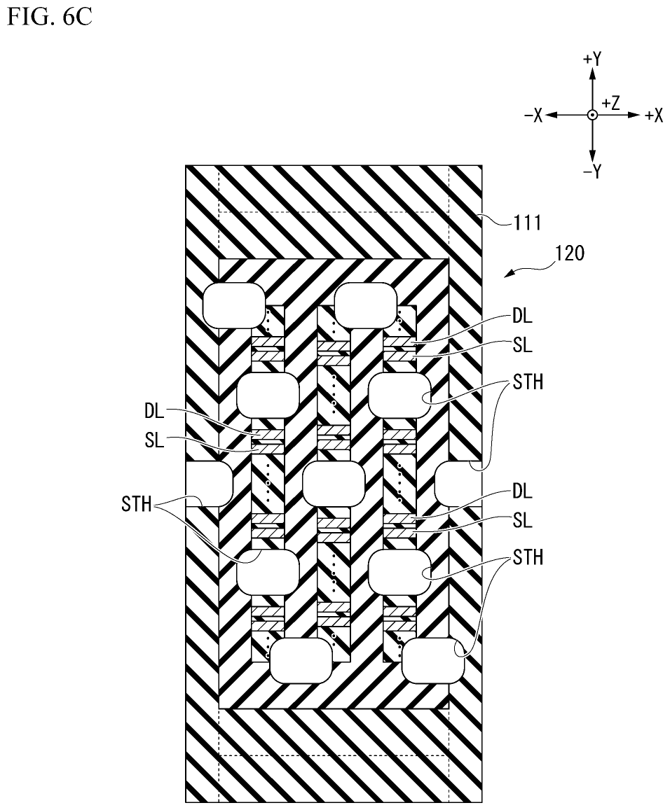

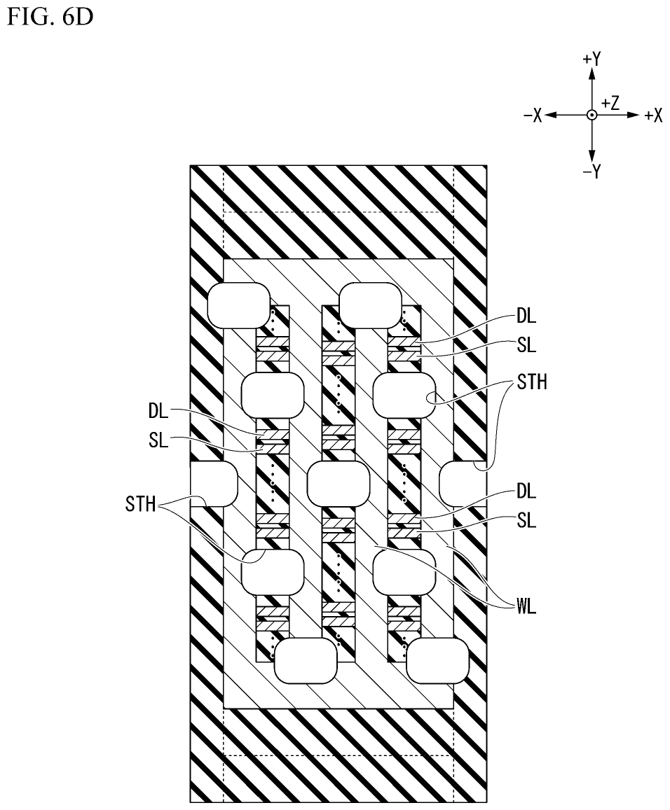

Next, as shown in FIG. 5H, a replacement process is performed. Specifically, first, a plurality of holes STH (see FIG. 6C) for the replacement process are formed in the intermediate structure 120. The holes STH penetrate the plurality of the insulating layers 40 and insulating layers 104 in the Z direction. Next, an etching solution (for example, hot phosphoric acid (H₃PO₄)) is supplied to the holes STH, and the insulating layers 104 are removed by etching.

Next, as shown in FIG. 51, the word line WL is formed in a space from which the insulating layer 104 has been removed. For example, first, the barrier metal film 31b is formed in the space from which the insulating layer 104 has been removed. Next, a metal material is supplied to the inside of the barrier metal film 31b to form the main body portion 31a. Next, as shown in FIG. 5J, the upper structure 60 is formed. With such a process, the semiconductor storage device 1 is completed.

Next, a partial process of the method of manufacturing the semiconductor storage device 1 will be further described. FIGS. 6A to 6D are cross-sectional views for explaining the method of manufacturing the semiconductor storage device 1. FIGS. 6A to 6D schematically show planar layouts of the semiconductor storage device 1 in the X direction and the Y direction.

FIG. 6A is a process corresponding to FIG. 5C and shows a process in which the plurality of the trenches MT are formed. In the embodiment, the intermediate structure 100 includes a plurality of support parts 131. The support parts 131 support the plurality of the stacked insulating layers 40 and insulating layers 104 not to collapse. FIG. 6B is a process corresponding to FIG. 5E and shows a process in which the insulator 111 is formed inside the trench MT.

FIG. 6C is a process corresponding to FIG. 5H and shows a process in which the plurality of the holes STH for the replacement process are formed in the intermediate structure 120. In the embodiment, the halls STH are provided at positions corresponding to the support parts 131. Therefore, the support parts 131 are removed. FIG. 6D is a process corresponding to FIG. 5I and shows a process in which the word line WL is formed.

### 4. ADVANTAGES

As a comparative example, a structure including a multi-layered body in which a plurality of word lines and a plurality of insulating layers are alternately stacked one layer by one layer on a substrate, a source line and a drain line extending in the multi-layered body in a thickness direction of the substrate, and memory layers and channel layers positioned between the source line and the drain line and adjacent to the plurality of the word lines and the plurality of the insulating layers may be conceived. In such a structure, electrical characteristics (for example, writing characteristics or erasing characteristics of data) of the semiconductor storage device may be deteriorated.

For example, in the above-described structure, since the channel layer is connected in a thickness direction of the substrate, a fringe electric field is also applied to a corresponding portion between two adjacent word lines in the channel layer, and a fringe transistor part is likely to be formed. As a result, when data is written at a low voltage, electrons are written to the transistor part on a lateral side of the word line in a memory layer and a threshold voltage increases, but electrons are not easily written to the corresponding portion (the fringe transistor part) between the two adjacent word lines and the threshold voltage does not increase. As a result, at the time of reading data, since the fringe transistor part is turned on while the transistor part on the lateral side of the word line in which the threshold voltage has increased is not turned on, it is determined that data is not in a stored state. Since such a read disturb event may occur, a problem may occur in reliability of the memory operation. A similar event may occur when data is erased.

Furthermore, in the structure of the comparative example described above, since a method of forming the source line and the drain line by introducing n-type impurities into polysilicon integrated with the channel is employed, it is difficult to form the source line and the drain line with a metal material. For example, if a metal material is embedded as the source line and the drain line, the metal is formed also in a portion including the channel, and resulting in a structure in which the source line and the drain line are short-circuited. Therefore, the source line and the drain line are formed of polysilicon doped with impurities. As a result, interconnection resistance of the source line and the drain line is high, and a sufficient read speed cannot be easily obtained due to an RC delay.

On the other hand, as shown in FIGS. 2 and 3, in the embodiment, the semiconductor storage device 1 includes the first word line WL (WL1) extending in the Y direction, the second word line WL (WL2) separated from the first word line WL in the Z direction and extending in the Y direction, the first channel 35A aligned with the first word line WL in the X direction and extending in the Y direction, the first memory film 33A positioned between the first word line WL and the first channel 35A in the X direction and extending in the Y direction, the second channel 35A aligned with the second word line WL in the X direction and extending in the Y direction, the second memory film 33A positioned between the second word line WL and the second channel 35A in the X direction and extending in the Y direction, the first insulating layer 40 positioned between the first word line WL and the second word line WL in the Z direction and between the first channel 35A and the second channel 35A in the Z direction, the first source line SL (SL1) positioned on a side opposite to the first word line WL with respect to the first channel 35A in the X direction and extending in the Z direction, and the first drain line DL (DL1) separated from the first source line SL in the Y direction, positioned on a side opposite to the first word line WL with respect to the first channel 35A in the X direction, and extending in the Z direction. According to such a configuration, the first channel 35A and the second channel 35A are separated from each other in the Z direction, and the fringe transistor part cannot be easily formed. Therefore, the semiconductor storage device 1 can improve electrical characteristics (for example, writing characteristics or erasing characteristics of data).

Furthermore, in the embodiment, the source line SL and the drain line DL contain a metal material. According to such a configuration, interconnection resistance of the source line SL and the drain line DL can be lowered, and an influence of an RC delay can be suppressed. As a result, a reading speed can be improved.

In the embodiment, the semiconductor storage device 1 further includes the first insulator 52 positioned between the first source line SL and the first drain line DL in the Y direction and extending in the X direction. The first source line SL1 and the first drain line DL1 can be electrically connected to each other via the first channel 35A. According to such a configuration, insulating properties between the first source line SL1 and the first drain line DL1 can be improved, and selective writing characteristics can be improved.

In the embodiment, the semiconductor storage device 1 further includes the third channel 35B aligned with the first word line WL from a side opposite to the channel 35A in the X direction and extending in the Y direction, the third memory film 33B positioned between the first word line WL and the third channel 35B in the X direction and extending in the Y direction, the fourth channel 35B aligned with the second word line WL from a side opposite to the second channel 35A in the X direction and extending in the Y direction, the fourth memory film 33B positioned between the second word line WL and the fourth channel 35B in the X direction and extending in the Y direction, the second source line SL (SL2) positioned on a side opposite to the first word line WL with respect to the third channel 35B in the X direction and extending in the Z direction, and the second drain line DL (DL2) separated from the second source line SL in the Y direction, positioned on a side opposite to the first word line WL1 with respect to the fourth channel 35B in the X direction, and extending in the Z direction. The first insulating layer 40 is positioned between the third channel 35B and the fourth channel 35B in the Z direction. According to such a configuration, the third channel 35B and the fourth channel 35B are separated from each other in the Z direction, and the fringe transistor part cannot be easily formed. Therefore, the semiconductor storage device 1 can further improve the electrical characteristics (for example, writing characteristics or erasing characteristics of data).

In the embodiment, the semiconductor storage device 1 further includes the third word line WL (WL3) positioned on a side opposite to the first word line WL with respect to the first source line SL in the X direction and extending in the first direction, the fourth word line WL (WL4) positioned on a side opposite to the second word line WL with respect to the first source line SL in the X direction and extending in the Y direction, the fifth channel 35B positioned between the third word line WL and the first source line SL in the X direction and extending in the Y direction, the fifth memory film 33B positioned between the third word line WL and the fifth channel 35B in the X direction and extending in the first direction, the sixth channel 35B positioned between the fourth word line WL and the first source line SL in the X direction and extending in the Y direction, the sixth memory film 33B positioned between the fourth word line WL and the sixth channel 35B in the X direction and extending in the Y direction, and the second insulating layer 40 positioned between the third word line WL and the fourth word line WL in the Z direction and between the fifth channel 35B and the sixth channel 35B in the Z direction. According to such a configuration, the fifth channel 35B and the sixth channel 35B are separated from each other in the Z direction, and the fringe transistor part cannot be easily formed. Therefore, the semiconductor storage device 1 can further improve the electrical characteristics (for example, writing characteristics or erasing characteristics of data).

### 5. OTHER APPLICATION EXAMPLES

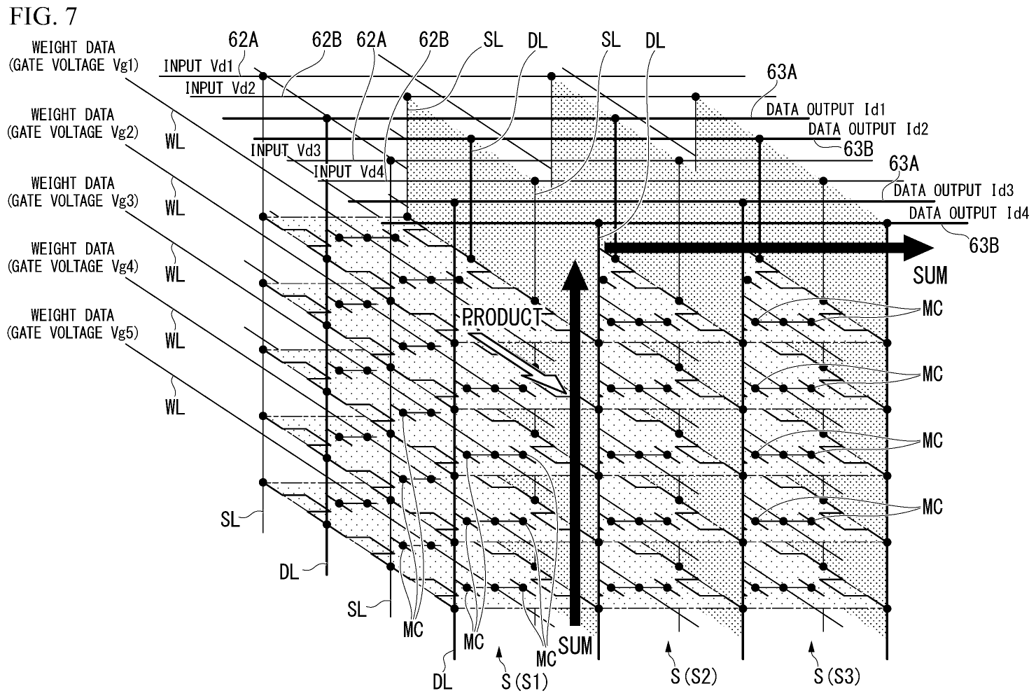

FIG. 7 is a diagram showing one application example of the structure according to the first embodiment. The semiconductor storage device 1 described in the first embodiment can be utilized as a multiply-accumulate calculation element (MAC). For example, the semiconductor storage device 1 can be utilized as a multiply-accumulate calculation element used for calculation in a learnt model of machine learning such as deep learning.

In the present application example, the plurality of the word lines WL included in the semiconductor storage device 1 are not connected to each other, and different voltages can be applied to the word lines WL independently of each other. A gate voltage Vg (gate voltage Vg1, Vg2, . . . ) corresponding to weight data is applied to each of the plurality of the word lines WL. A voltage Vd (voltages Vd1, Vd2, . . . ) corresponding to input data is applied to each of the plurality of the source lines SL. A current Id (currents Id1, Id2, . . . ) corresponding to output data flows in each of the plurality of the drain lines DL. An amount of the current Id indicating contents of the output data is an addition result obtained by adding a multiplication result (product) in each memory cell MC for the plurality of the memory cells MC included in the same column S, and further adding the addition results for the plurality of the columns S (S1, S2, . . . ).

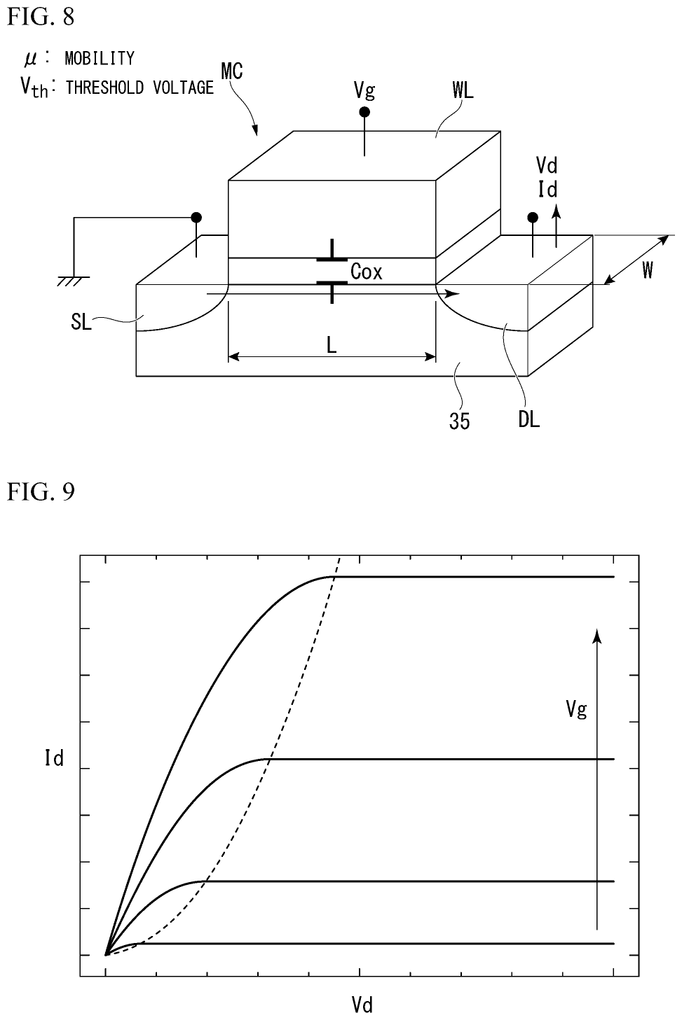

FIG. 8 is a view for explaining expression (1) to be described later. As shown in FIG. 8, in a transistor corresponding to the memory cell MC, a gate voltage applied to a gate (word line WL) is defined as Vg, a gate length is defined as L, a gate width is defined as W, a gate capacitance is defined as Cox, a current flowing through a drain (drain line DL) is defined as a drain current Id, a voltage of the drain current Id is defined as a drain voltage Vd, mobility is defined as μ, and a threshold voltage is defined as Vth. In this case, an amount of the drain current Id is calculated by the following expression (1).

$$\begin{matrix}Id = W \times μ \times [ Cox ( Vg - Vth ) + Cox ( Vg - Vth - Vg ) ] / 2 \times ( Vg / L ) \\ = ( W / L ) μ Cox [ ( Vg - Vth ) - Vg / 2 ] Vg\end{matrix} \qquad ( 1 )$$

FIG. 9 is another diagram for explaining one application example. The solid line in FIG. 9 shows a relationship between the gate voltage Vg and the drain voltage Vd. The broken line in FIG. 9 indicates an amount of the drain current Id with respect to the gate voltage Vg and the drain voltage Vd. The amount of the drain current Id is determined on the basis of a product of the gate voltage Vg and the drain voltage Vd.

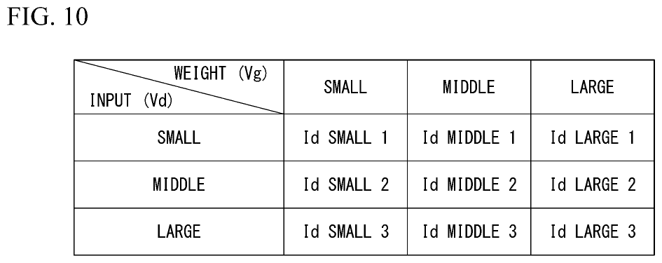

FIG. 10 is another diagram for explaining one application example. As shown in FIG. 10, the amount of the drain current Id is determined on the basis of a relationship between the gate voltage Vg and the drain voltage Vd. For example, when the input data voltage Vd is small and the weight data voltage Vg is small, the drain current Id is “Id small 1”. When the input data voltage Vd is middle and the weight data voltage Vg is small, the drain current Id is “Id small 2”. When the input data voltage Vd is large and the weight data voltage Vg is small, the drain current Id is “Id small 3”. When the input data voltage Vd is small and the weight data voltage Vg is middle, the drain current Id is “Id middle 1”. When the input data voltage Vd is middle and the weight data voltage Vg is middle, the drain current Id is “Id middle 2”. When the input data voltage Vd is large and the weight data voltage Vg is middle, the drain current Id is “Id middle 3”. When the input data voltage Vd is small and the weight data voltage Vg is large, the drain current Id is “Id large 1”. When the input data voltage Vd is middle and the weight data voltage Vg is large, the drain current Id is “Id large 2”. When the input data voltage Vd is large and the weight data voltage Vg is large, the drain current Id is “Id large 3”. Here, “Id small 1”, “Id small 2”, “Id small 3”, “Id middle 1”, “Id middle 2”,

“Id middle 3”, “Id large 1”, “Id large 2”, and “Id large 3” mean amounts of the drain current Id. “Id small 3” is higher than “Id small 2” in amount of the current. “Id small 2” is higher than “Id small 1” in amount of the current. “Id middle 3” is higher than “Id middle 2” in amount of the current. “Id middle 2” is higher than “Id middle 1” in amount of the current. “Id large 3” is higher than “Id large 2” in amount of the current.

“Id large 2” is higher than “Id large 1” in amount of the current. Particularly, the semiconductor storage device 1 as a multiply-accumulate calculation element can sequentially add and output the drain currents Id of the plurality of the memory cells MC. Therefore, a result of the multiply-accumulate calculation can be output.

### Second Embodiment

Next, a second embodiment will be described. The second embodiment is different from the first embodiment in that an insulating layer 151 is provided between the source line SL and the drain line DL, and the semiconductor substrate 11. Configurations other than those described below are the same as the configurations of the first embodiment.

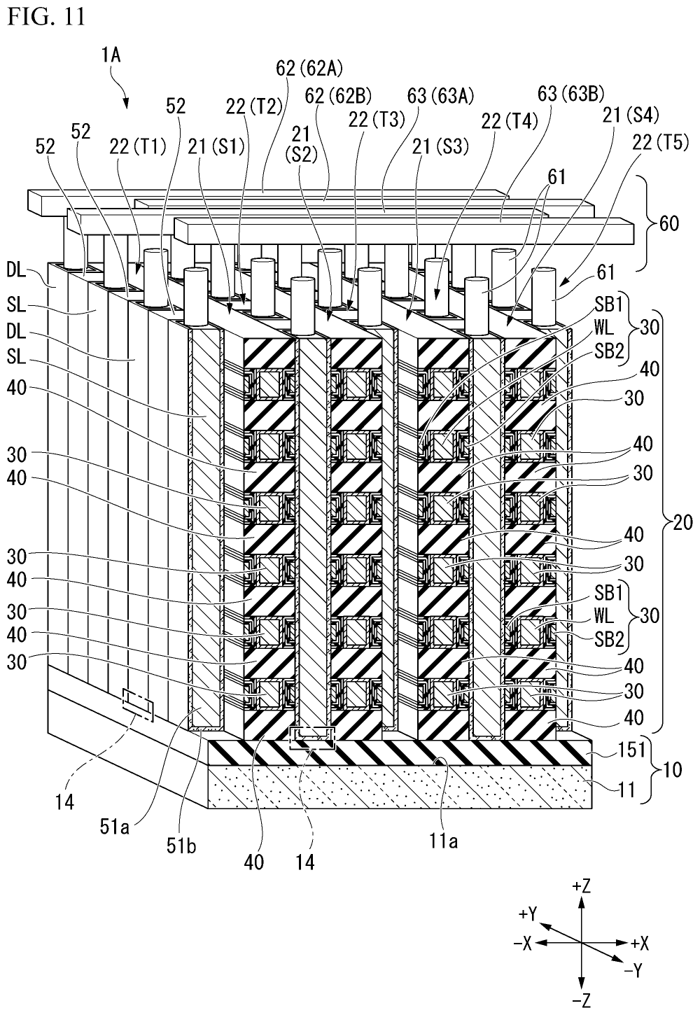

FIG. 11 is a perspective cross-sectional view showing a semiconductor storage device lA according to the second embodiment. A lower structure 10 of the semiconductor storage device 1A includes the insulating layer 151 instead of the stopper layer 12 and the diffusion layer 13. The insulating layer 151 functions as a stopper layer in etching and also functions as a layer that secures an electrical withstand voltage between a source line SL a drain line DL. The insulating layer 151 is formed of, for example, aluminum oxide (AlO), hafnium oxide (HfO), zirconia (ZrO), titanium oxide (TiO), oxygen-doped silicon carbide (SiCO), nitrogen-doped silicon carbide (SiCN), boron nitride (BN), high temperature carbon, or the like. Even with such a configuration, the same operation as that of the first embodiment can be expected.

### Third Embodiment

Next, a third embodiment will be described. In the third embodiment, disposition layouts of a source line SL and a drain line DL are different from those of the first embodiment. Configurations other than those described below are the same as the configurations of the first embodiment.

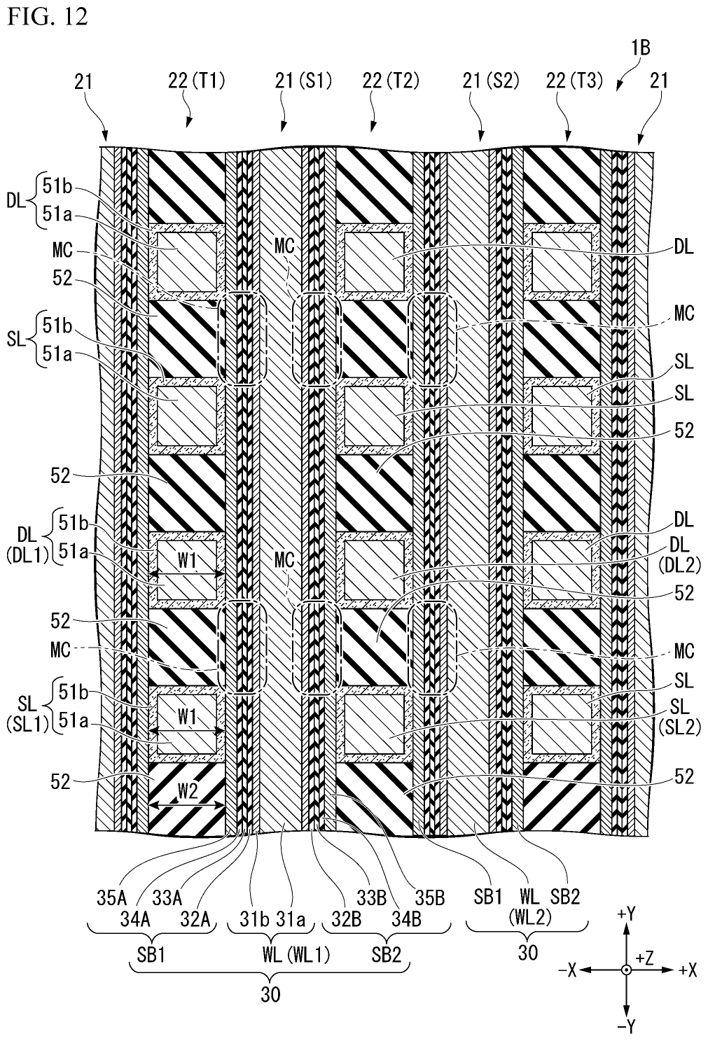

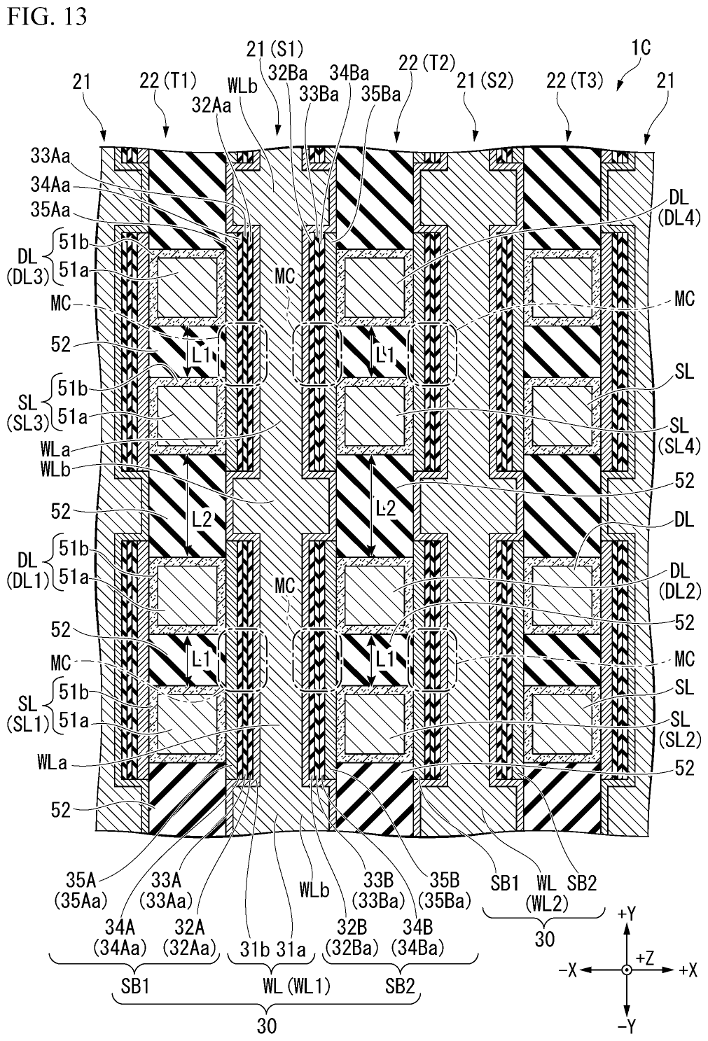

FIG. 12 is a cross-sectional view showing a semiconductor storage device 1B according to the third embodiment. In the first embodiment described above, the plurality of the source lines SL and the plurality of the drain lines DL included in the even-numbered column T (T2, T4, . . . ) are disposed to be shifted in the Y direction with respect to the plurality of the source lines SL and the plurality of the drain lines DL included in the odd-numbered column T (T1, T3, . . . ). On the other hand, in the third embodiment, a plurality of source lines SL and a plurality of drain lines DL included in an even-numbered column T (T2, T4, . . . ) and a plurality of source lines SL and a plurality of drain lines DL included in an odd-numbered column T (T1, T3, . . . ) are disposed at the same position in the Y direction. In other words, the plurality of the source lines SL and the plurality of the drain lines DL included in the even-numbered column T (T2, T4, . . . ) and the plurality of the source lines SL and the plurality of the drain lines DL included in the odd-numbered column T (T1, T3, . . . ) are aligned in the X direction. Even with such a configuration, improvement in electrical characteristics can be achieved as in the first embodiment.

### Fourth Embodiment

Next, a fourth embodiment will be described. The fourth embodiment is different from the third embodiment in that a plurality of memory cells MC aligned in the Y direction are separated from each other. Configurations other than those described below are the same as the configurations of the third embodiment.

FIG. 13 is a cross-sectional view showing a semiconductor storage device IC according to the fourth embodiment. In this embodiment, a memory cell MC is provided between one set of a source line SL and a drain line DL that are electrically connected to each other. Then, the plurality of the memory cells MC aligned in the Y direction are separated from each other. In the embodiment, a distance L1 in the Y direction between one set of the source line SL and the drain line DL corresponding to the same memory cell MC is smaller than a distance L2 in the Y direction between one set of the source line SL and the drain line DL not corresponding to the same memory cell MC.

In the embodiment, in a first side structure SB1, a block insulating film 32A, a memory film 33A, a tunnel insulating film 34A, and a channel 35A are separated between the plurality of the memory cells MC aligned in the Y direction. In this case, a block insulating film 32Aa, a memory film 33Aa, a tunnel insulating film 34Aa, and a channel 35Aa corresponding to the individual memory cells MC are formed. Similarly, in the second side structure SB2, a block insulating film 32B, a memory film 33B, a tunnel insulating film 34B, and a channel 35B are separated between the plurality of the memory cells MC aligned in the Y direction. In this case, a block insulating film 32Ba, a memory film 33Ba, a tunnel insulating film 34Ba, and a channel 35Ba corresponding to the individual memory cells MC are formed.

More specifically, a first column T1 includes a source line SL (first source line SL1), a drain line DL (first drain line DL1), another source line SL (third source line SL3), and another drain line DL (third drain line DL3) which are aligned in order in the Y direction. The third source line SL3 is positioned on a side opposite to the first source line SL1 with respect to the first drain line DLL The third drain line DL3 is positioned on a side opposite to the first drain line DL1 with respect to the third source line SL3. The distance L1 in the Y direction between the first source line SL1 and the first drain line DL1 is smaller than the distance L2 between the first drain line DL1 and the third source line SL3. Similarly, the distance L1 in the Y direction between the third source line SL3 and the third drain line DL3 is smaller than a distance L3 between the first drain line DL1 and the third source line SL3.

Then, the block insulating film 32Aa, the memory film 33Aa, the tunnel insulating film 34Aa, and the channel 35Aa which are aligned with the first source line SL1 and the first drain line DL1 in the X direction, and the block insulating film 32Aa, the memory film 33Aa, the tunnel insulating film 34Aa, and the channel 35Aa which are aligned with the third source line SL3 and the third drain line DL3 in the X direction are separated from each other in the Y direction. In the embodiment, the memory film 33Aa and the channel 35Aa aligned with the first source line SL1 and the first drain line DL1 in the X direction are examples of a “first memory film” and a “first channel”. The memory film 33Aa and the channel 35Aa aligned with the third source line SL3 and the third drain line DL3 in the X direction are examples of a “seventh memory film” and a “seventh channel”.

Similarly, a second column T2 includes a source line SL (second source line SL2), a drain line DL (second drain line DL2), another source line SL (fourth source line SL4), and another drain line DL (fourth drain line DL4) which are aligned in order in the Y direction. The fourth source line SL4 is positioned on a side opposite to the second source line SL2 with respect to the second drain line DL2. The fourth drain line DL4 is positioned on a side opposite to the second drain line DL2 with respect to the fourth source line SL4. A distance L1 in the Y direction between the second source line SL2 and the second drain line DL2 is smaller than a distance L2 between the second drain line DL2 and the fourth source line SL4. Similarly, the distance L1 in the Y direction between the fourth source line SL4 and the fourth drain line DL4 is smaller than the distance L2 between the second drain line DL2 and the fourth source line SL4.

Then, the block insulating film 32Ba, the memory film 33Ba, the tunnel insulating film 34Ba, and the channel 35Ba which are aligned with the second source line SL2 and the second drain line DL2 in the X direction, and the block insulating film 32Ba, the memory film 33Ba, the tunnel insulating film 34Ba, and the channel 35Ba which are aligned with the fourth source line SL4 and the fourth drain line DL4 in the X direction are separated from each other in the Y direction.

In the embodiment, each word line WL includes a plurality of main body portions WLa and a plurality of large width portions WLb. The main body portion WLa is aligned with the block insulating films 32Aa and 32Ba, the memory films 33Aa and 33Ba, the tunnel insulating films 34Aa and 34Ba, and the channels 35Aa and 35Ba in the X direction. The main body portion WLa aligned with the first source line SL1 and the first drain line DL1 in the X direction is an example of a “first portion”. The main body portion WLa aligned with the third source line SL3 and the third drain line DL3 in the X direction is an example of a “second portion”.

The large width portion WLb is not aligned with the block insulating films 32Aa and 32Ba, the memory films 33Aa and 33Ba, the tunnel insulating films 34Aa and 34Ba, and the channels 35Aa and 35Ba in the X direction. The main body portion WLa and the large width portion WLb are alternately disposed in the Y direction.

A part of the large width portion WLb is provided between the plurality of the memory cells MC adjacent to each other in the Y direction in the first side structure SB1, and is positioned between the plurality of the block insulating films 32Aa adjacent to each other in the Y direction, between the plurality of the memory films 33Aa adjacent to each other in the Y direction, between the plurality of the tunnel insulating films 34Aa adjacent to each other in the Y direction, and between the plurality of the channels 35Aa adjacent to each other in the Y direction. The large width portion WLb positioned between the first portion and the second portion of the word line WL described above is an example of a “third portion”.

Similarly, another part of the large width portion WLb is provided between the plurality of the memory cells MC adjacent to each other in the Y direction in the second side structure SB2, and is positioned between the plurality of the block insulating films 32Ba adjacent to each other in the Y direction, between the plurality of the memory films 33Ba adjacent to each other in the Y direction, between the plurality of the tunnel insulating films 34Ba adjacent to each other in the Y direction, and between the plurality of the channels 35Ba adjacent to each other in the Y direction.

Next, a method of manufacturing the semiconductor storage device 1C according to the fourth embodiment will be described. In the method of manufacturing the semiconductor storage device 1C, the processes shown in FIGS. 5C and 5D of the first embodiment (that is, the process in which the recesses 105A and 105B are formed after processing of the trench MT, and the block insulating films 32A and 32B, the memory films 33A and 33B, the tunnel insulating films 34A and 34B, and the channels 35A and 35B are formed in the recesses 105A and 105B) are not performed. In the method of manufacturing the semiconductor storage device 1C, after the process shown in FIG. 5F of the first embodiment (the process of forming the hole H), an etching solution (for example, hot phosphoric acid (H₃PO₄)) is supplied to each hole H to partially remove both end portions of the insulating layer 104 in the X direction by etching. Therefore, the side surface of the insulating layer 104 in the −X direction is recessed in the +X direction with respect to the side surface of the insulating layer 40 in the −X direction, and thereby a plurality of first recesses separated from each other in the Y direction are formed. Similarly, the side surface of the insulating layer 104 in the +X direction is recessed in the −X direction with respect to the side surface of the insulating layer 40 in the +X direction, and thereby a plurality of second recesses separated from each other in the Y direction are formed.

Next, materials serving as sources of the block insulating film, the memory film, the tunnel insulating film, and the channel are supplied to the inner surface of the hole H. Then, an unnecessary portion is removed by etching. In the embodiment, after the insides of the first recess and the second recess are closed by the material of the channel, etch back is performed only on the material of the channel, or up to the material of the channel, the material of the tunnel insulating film, and the material of the memory film using a choline-based wet solution to form the channel 35 or the like only inside the first recess and the second recess. Therefore, the block insulating film 32Aa, the memory film 33Aa, the tunnel insulating film 34Aa, and the channel 35Aa are formed on an inner surface of the first recess. The block insulating film 32Ba, the memory film 33Ba, the tunnel insulating film 34Ba, and the channel 35Ba are formed on an inner surface of the second recess. Therefore, a plurality of first structural parts 21 are formed.

Here, intervals between the plurality of the sources SL and the plurality of the drain lines DL aligned in the Y direction (intervals between the plurality of the holes H) are unequal. Then, the distance L1 between the source line SL and the drain line DL corresponding to the same memory cell MC is smaller than the distance L2 between the source line SL and the drain line DL corresponding to a portion between the plurality of the memory cells MC. For example, according to the above-described configuration, a structure in which the channel 35 is separated is formed as shown in FIG. 16 according to an etching amount (recess amount) with respect to the insulating layer 104.

According to such a configuration, improvement in electrical characteristics can be achieved as in the first embodiment. Furthermore, according to the configuration of the embodiment, a disturbance can be suppressed as compared with the first embodiment. Therefore, improvement in electrical characteristics can be further achieved. Furthermore, the configuration of the embodiment may be realized in combination with the configuration in which the plurality of the source lines SL and the plurality of the drain lines DL included in the even-numbered column T (T2, T4, . . . ) are disposed to be shifted in the Y direction with respect to the plurality of the source lines SL and the plurality of the drain lines DL included in the odd-numbered column T (T1, T3, . . . ) as in the first embodiment.

### MODIFIED EXAMPLE

In the first to fourth embodiments, the memory cell MC having a charge trap film as the memory film 33 has been described. However, the configuration of the memory cell MC is not limited to the above-described example. For example, the memory cell MC may be a ferroelectric gate field effect transistor (FeFET) having a ferroelectric film as the memory film 33. A ferroelectric film stores a data value according to, for example, an orientation of polarization. The ferroelectric film is formed of, for example, hafnium oxide (HfO), zirconia (ZrO), hafnium-zirconia oxide (HfZrO), or the like.

Preferred embodiments and modified examples have been described above. However, the embodiments and modified examples are not limited to the examples described above.

According to at least one embodiment described above, the semiconductor storage device includes an insulating layer positioned between the first word line and the second word line in the Z direction and between the first channel and the second channel in the Z direction. According to such a configuration, improvement in electrical characteristics can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a substrate;
a first word line extending in a first direction parallel to a surface of the substrate;
a second word line separated from the first word line in a second direction, the second direction being a thickness direction of the substrate, the second word line extending in the first direction;
a first channel aligned with the first word line in a third direction, the third direction crossing the first direction and the second direction, the first channel extending in the first direction;
a first memory film between the first word line and the first channel in the third direction, the first memory film extending in the first direction;
a second channel aligned with the second word line in the third direction, the second channel extending in the first direction;
a second memory film between the second word line and the second channel in the third direction, the second memory film extending in the first direction;
a first insulating layer between the first word line and the second word line in the second direction, the first insulating layer being between the first channel and the second channel in the second direction;
a first source line on a side opposite to the first word line with respect to the first channel in the third direction, the first source line extending in the second direction; and
a first drain line separated from the first source line in the first direction, the first drain line being on a side opposite to the first word line with respect to the first channel in the third direction, the first drain line extending in the second direction.

2. The semiconductor storage device according to claim 1, wherein
the first source line is on a side opposite to the second word line with respect to the second channel in the third direction, and
the first drain line is on a side opposite to the second word line with respect to the second channel in the third direction.

3. The semiconductor storage device according to claim 1, further comprising:
a first insulator between the first source line and the first drain line in the first direction, the first insulator extending in the third direction, wherein
the first source line and the first drain line are electrically connectable to each other via the first channel.

4. The semiconductor storage device according to claim 1, further comprising:
a third channel aligned with the first word line from a side opposite to the first channel in the third direction, the third channel extending in the first direction;
a third memory film between the first word line and the third channel in the third direction, the third memory film extending in the first direction;
a fourth channel aligned with the second word line from a side opposite to the second channel in the third direction, the fourth channel extending in the first direction;
a fourth memory film between the second word line and the fourth channel in the third direction, the fourth memory film extending in the first direction;
a second source line on a side opposite to the first word line with respect to the third channel in the third direction, the second source line extending in the second direction; and
a second drain line separated from the second source line in the first direction, the second drain line being on a side opposite to the first word line with respect to the third channel in the third direction, the second drain line extending in the second direction, wherein
the first insulating layer is between the third channel and the fourth channel in the second direction.

5. The semiconductor storage device according to claim 1, further comprising:
a third word line on a side opposite to the first word line with respect to the first source line in the third direction, the third word line extending in the first direction;
a fourth word line on a side opposite to the second word line with respect to the first source line in the third direction, the fourth word line extending in the first direction;
a fifth channel between the third word line and the first source line in the third direction, the fifth channel extending in the first direction;
a fifth memory film between the third word line and the fifth channel in the third direction, the fifth memory film extending in the first direction;
a sixth channel between the fourth word line and the first source line in the third direction, the sixth channel extending in the first direction;
a sixth memory film between the fourth word line and the sixth channel in the third direction, the sixth memory film extending in the first direction; and
a second insulating layer between the third word line and the fourth word line in the second direction, the second insulating layer being between the fifth channel and the sixth channel in the second direction.

6. The semiconductor storage device according to claim 1, wherein
each of the first source line and the first drain line contains a metal material.

7. The semiconductor storage device according to claim 1, wherein
each of the first source line and the first drain line includes a surface layer portion and a main body portion, the surface layer portion having at least a portion formed in an annular shape, the main body portion being on an inner side of the surface layer portion,
the surface layer portion contains a semiconductor material doped with impurities, and
the main body portion contains a metal material.

8. The semiconductor storage device according to claim 1, wherein
the first memory film includes a charge trap film or a ferroelectric film.

9. The semiconductor storage device according to claim 1, further comprising
a PN junction part or an insulating layer, being between each of the first source line and the first drain line, and the substrate in the second direction.

10. The semiconductor storage device according to claim 1, further comprising:
a seventh channel separated from the first channel in the first direction, the seventh channel being aligned with the first word line in the third direction, the seventh channel extending in the first direction;
a seventh memory film separated from the first memory film in the first direction, the seventh memory film being between the first word line and the seventh channel in the third direction, the seventh memory film extending in the first direction;
a third source line on a side opposite to the first word line with respect to the seventh channel in the third direction, the third source line extending in the second direction; and
a third drain line separated from the third source line in the first direction, the third drain line being on a side opposite to the first word line with respect to the seventh channel in the third direction, the third drain line extending in the second direction.

11. The semiconductor storage device according to claim 10, wherein
the first word line includes:
a first portion aligned with the first channel in the third direction;
a second portion aligned with the seventh channel in the third direction; and
a third portion having a larger width in the third direction than that of the first portion, the third portion including a portion between the first channel and the seventh channel in the first direction.
